(19) United States
(12) Patent Application Publication
(10) Pub. No.: US 2013/0313579 A1
(43) Pub. Date: Nov. 28, 2013

(54) DILUTE SN-DOPED GE ALLOYS

(71) Applicants: John Kouvetakis, Mesa, AZ (US); Richard Beeler, Tempe, AZ (US); Jose Menendez, Tempe, AZ (US); Radek Roucka, Mountain View, CA (US)

(72) Inventors: John Kouvetakis, Mesa, AZ (US); Richard Beeler, Tempe, AZ (US); Jose Menendez, Tempe, AZ (US); Radek Roucka, Mountain View, CA (US)

(21) Appl. No.: 13/885,121

(22) PCT Filed: Nov. 18, 2011
(86) PCT No.: PCT/US11/61375

§ 371 Date: Aug. 7, 2013

Related U.S. Application Data
(60) Provisional application No. 61/415,542, filed on Nov. 19, 2010.
(60) Provisional application No. 61/478,666, filed on Apr. 25, 2011.

(51) Int. Cl. H01L 29/12; H01L 31/028; H01L 21/02

(52) U.S. Cl. CPC H01L 29/12; H01L 21/02104; H01L 31/028
USPC 257/80; 257/201; 438/478; 257/438; 257/443; 257/458; 420/556

(57) ABSTRACT

Detectors based on such Ge(Sn) alloys of the formula Ge₁₋ₓSnₓ (e.g., 0<x<0.01) have increased responsivity while keeping alloy scattering to a minimum. Such small amounts of Sn are also useful for improving the performance of the recently demonstrated Ge-on-Si laser structures, since the addition of Sn monotonically reduces the separation between the direct and indirect minima in the conduction band of Ge. Thus, provided herein are Ge(Sn) alloys of the formula Ge₁ₓSnₓ, wherein x is less than 0.01, wherein the alloy is optionally n-doped or p-doped; and assemblies and photodiodes comprising the same, and methods for their formation.

### CROSS-REFERENCE TO RELATED APPLICATIONS

This application claims the benefit of the filing dates of U.S. Provisional Application Ser. No. 61/415,542 filed Nov. 19, 2010; and U.S. Provisional Application Ser. No. 61/478,666, filed Apr. 25, 2011, both of which are hereby incorporated by reference in their entirety.

### STATEMENT OF GOVERNMENT FUNDING

The invention described herein was made in part with government support under grant number DOD AFOSR FA9550-06-01-0442 awarded by the United States Air Force (MURI program); grant number DE-FG36-08GO18003 awarded by the Department of Energy; and grant number DMR-0907600, awarded by the National Science Foundation. The United States Government has certain rights in the invention.

### FIELD OF THE INVENTION

The invention generally relates to macro-Sn-doped germanium alloys, methods for their preparation and use, and devices and methods for making devices, such as photodiodes, comprising the same.

### BACKGROUND OF THE INVENTION

Alloys of Ge and Sn are attracting increasing attention as the only group-IV system with a predicted direct band gap and enhanced absorption in the near-infrared. While different synthetic approaches have been pursued, (see, Shah et al., J. Cryst. Growth 83, 3 (1987); Gurdal et al., Appl. Phys. Lett. 67 (7), 956 (1995); He and Atwater, Appl. Phys. Lett. 68 (5), 664 (1996); Saidov et al., Technical Physics Letters 27 (Copyright 2001, IEE), 698 (2001); Razzakov, Doklady Physics 46 (Copyright 2001, IEE), 548 (2001); Taraci et al., Appl. Phys. Lett. 78, 3607 (2001); Pérez Ladrón de Guevara et al., Appl. Phys. Lett. 83 (24), 4942 (2003); and Perez Ladron de Guevara et al., Appl. Phys. Lett. 84 (22), 4532 (2004)) the chemical vapor deposition (CVD) method introduced by Bauer and coworkers (Appl. Phys. Lett. 81, 2992 (2002)), which uses mixtures of digermane-Ge₂H₆— and deuterated stannane-SnD₄-, is particularly attractive for its simplicity and compatibility with silicon technologies.

For the past few years the CVD growth conditions for films with Sn contents of 2% and higher have been systematically refined (see D'Costa et al., Semicond. Sci. Technol. 24 (11), 115006 (2009); and Kouvetakis et al., IEEE Photonics J. 2 (6), 924 (2010)), with the goal of achieving significantly enhanced absorption over the entire range of telecommunication windows (a Ge_{0.98}Sn_{0.02} alloy has the same band gap as an In_{0.53}Ga_{0.47}As alloy lattice-matched to InP, a standard near-infrared detector material) as well as eventually demonstrating a direct gap alloy (predicted for Sn concentrations in the 6%-11% range, see D'Costa et al., Phys. Rev. B 73 (12), 125207 (2006)). On the other hand, there are applications for which smaller Sn concentrations may be sufficient and even desirable. For example using the known compositional dependence of the direct band gap, it is estimated that only 0.2% of Sn is needed to double the room-temperature absorption coefficient at 1550 nm relative to pure Ge (see D'Costa et al., Semicond. Sci. Technol. 24 (11), 115006 (2009)).

For standard Ge-on-Si material, the low absorption at 1550 nm creates serious difficulties for integrated detectors on Si platforms. In the case of normal-incidence devices, attempts to compensate the poor absorption by utilizing thicker films lead to reduced bandwidth (see, Colace et al., Lightwave Technology, Journal of 26 (16), 2954 (2008); Colace, Photonics Journal, IEEE 1 (2), 69 (2009); Morse et al., presented at the 2009 Conference on Optical Fiber Communication—OFC 2009, 22-26 Mar. 2009, Piscataway, N.J., USA, 2009 (unpublished); and Michel et al., Nat Photon 4 (8), 527 (2010)). Waveguide geometries make it possible to decouple bandwidth from responsivity, but even these structures would benefit from increased absorption at 1550 nm. The standard approach to effect this increase is the introduction of tensile strain (Liu et al., Appl. Phys. Lett. 87 (10), 103501 (2005)), which appears in Ge films on Si due to the thermal expansion mismatch between the two materials (see Ishikawa et al., Appl. Phys. Lett. 82 (13), 2044 (2003)). However, the magnitude of this strain depends strongly on the growth conditions. In particular, it usually requires high growth temperatures, which are incompatible with CMOS fabrication.

### SUMMARY OF THE INVENTION

Detectors based on diluted Ge₁₋ₓSnₓ alloys (e.g., 0<x<0.01)(“Ge(Sn)”) have the benefit of increased responsivity and spectral coverage while keeping alloy scattering to a minimum. Reduced alloy scattering is of interest from the electronic properties perspective. Optoelectronically, a shift in absorption edge and any change in the relative positions of direct/indirect bandgaps can lead to marked optoelectronic properties.

Low Sn concentrations can be achieved by reducing the amount of SnD₄ in the reaction mixture. However, since the presence of SnD₄ appears to play a critical role in promoting layer-by-layer growth, the Sn concentration may only be reduced to a point without compromising film quality.

The methods described herein circumvent the Stranski-Krastanov (S-K) mechanism that characterizes the growth of Ge on Si. Under the S-K mechanism, Ge generally deposits on Si surfaces through nucleation and coalescence of adsorbate ‘islands’. However, the presence of SnD₄, even at the low levels used herein, promotes a layer-by-layer crystal assembly while maintaining unprecedented high growth rates at the low temperatures employed.

The exact mechanism involving SnD₄ in this regard is not explicitly known however the presence of the compound in the growth front appears to mediate lateral diffusion and at the same time promote the evolution of stable H₂ byproducts from the growing layer, leaving behind thick and monocrystalline films with uniform thicknesses and atomically flat surfaces. Herein, Ge-like materials incorporating very low Sn (e.g., 0.05-0.3% Sn range; about 7-13×10¹⁹ atoms/cm³) are illustrated that can be formed in a controlled and reproducible manner.

In comparison, the use of pure digermane under the same conditions of temperature and pressure does not produce any measurable film growth.

Such Ge(Sn) alloys, display a clear shift in the absorption edge to longer wavelengths as observed in devices containing these materials provided herein, indicating a direct band gap reduction that is clearly measurable even for a Sn concentration as low as 0.25%. Further, this shift to longer wavelengths is not accompanied by a broadening of the absorption edge, as seen in the case of higher Sn-content GeSn alloys, such as Ge_{0.98}Sn_{0.02}.

Accordingly, in one aspect, the present disclosure provides Ge(Sn) alloys of the formula Ge₁₋ₓSnₓ, wherein x is greater than 0 and less than 0.01 (e.g, greater than 0 and less than or equal to about 0.003, such as, between about 0.0005 and about 0.003), wherein the alloy is optionally n-doped or p-doped.

In another aspect, the present disclosure provides Ge(Sn) alloys of the formula Ge₁₋ₓSnₓ, wherein x is greater than 0 and less than 0.01 (e.g, greater than 0 and less than or equal to about 0.003, such as, between about 0.0005 and about 0.003), wherein the alloy is optionally n-doped and/or p-doped to provide a fully or partially compensated layer. Simultaneous p- and n-type doping can be used to provide partially or fully compensated doped materials.

In another aspect, the present disclosure proves assemblies comprising a substrate and a layer consisting essentially of a Ge(Sn) alloy, as described herein, formed over the substrate.

In another aspect, the present disclosure provides methods for forming an assembly comprising contacting a surface layer of a substrate with a vapor comprising Ge₂H₆ and SnD₄ under conditions suitable for forming a Ge(Sn) alloy layer of the formula Ge₁₋ₓSnₓ over the surface layer, wherein x is greater than 0 and less than 0.01 (e.g, greater than 0 and less than or equal to about 0.003, such as, between about 0.0005 and about 0.003), and wherein the surface layer comprises Si.

In another aspect, the present disclosure provides photodiodes comprising a doped substrate having a surface layer; an intrinsic Ge(Sn) alloy layer formed directly over the Si surface layer; and a second Ge(Sn) alloy layer directly over the intrinsic Ge(Sn) alloy layer, wherein one of the substrate surface layer and the second Ge(Sn) alloy layer is p-doped and the other is n-doped.

### BRIEF DESCRIPTION OF THE DRAWINGS

FIG. 1a shows a high resolution electron micrograph of 1 μm thick film containing dopant levels of Sn (10¹⁹/cm³); the area within the field of view appears completely devoid of threading defects and exhibits a flat surface.

FIG. 1b is a high resolution image showing edge type dislocations localized to the interface between Ge and Si(100).

FIG. 1c shows a high resolution XRD plots indicate a nearly strain free state and very narrow mosaic spreads as evidenced by sharp and intense (224) reciprocal space maps and (004) peaks. A rocking curve of the latter exhibits a FWHM of 140 arcseconds which is well beyond the state-of-the-art of Ge on Si materials.

FIG. 2a is a schematic representation of the Ge-based photodiode in n-Si(100)/i-GeSn/p-GeSn geometry

FIG. 2b is a corresponding SIMS elemental profiles showing the distribution of B, Sn, Ge and Si atoms throughout the entire film structure of FIG. 2a.

FIG. 3a shows I-V graphs obtained from GeSn and Ge reference device mesas with sizes of 100 μm in diameter.

FIG. 3b contains Arrhenius plots of the dark current density at selected reverse bias values (activation energies are obtained from the line slopes).

FIG. 4 show the responsivities of heterostructure pin diodes on n-type Si substrates. Solid circles correspond to a device with a Ge_{0.9975}Sn_{0.0025} intrinsic layer (490 nm); empty squares correspond to a device with a pure Ge intrinsic layer (350 nm). The solid lines represent a fit with the theoretical model described in the text, using the independently measured composition and strain values. The inset shows the region near 1550 nm in more detail. The dotted lines show the expected responsivity if the layers were perfectly strain-free. The vertical dashed line marks the 1550 nm wavelength.

FIG. 5 shows responsive derivatives of the model responsivities in FIG. 4, and the dotted lines are the derivatives of the same theoretical calculations but setting the strain equal to zero. The vertical line corresponds to 1550 nm. The insets show in more detail the spectral region around this wavelength.

FIG. 6 is a graph of responsivity versus bias under illumination by a laser diode at 1300 nm (a) and 1550 nm (b).

FIG. 7 shows the experimental optical absorption for Ge (circles). The solid line is the absorption calculated with the model described in the text. The dashed line is the absorption corresponding to the bands that determine the E₀ gap at the center of the Brillouin zone, assumed to be parabolic.

FIG. 8 shows random RBS spectra of Ge₁₋ₓSnₓ films containing 0.6, 1.5 and 3.0% Sn and exhibiting thicknesses of about 620 nm and about 600 nm and about 450 nm, respectively. The inset is an enlarged view of the Sn signal shown as a shoulder adjacent to the main Ge peak. Note that although the compositions of the samples are derived from a detailed fit of the entire RBS spectrum using the program RUMP, the intensities shown in the inset scale linearly with Sn content.

FIG. 9 shows (a) (224) Reciprocal space maps of SnₓGe₁₋ₓ alloys with compositions 0.6, 1.5 and, 3.0% Sn showing corresponding strains of −0.14, −0.15 and −0.14, respectively. These data are used in combination with an extensive set shown in part (b) to determine an accurate composition-structure relationship for dilute GeSn alloys used in the PL investigations. (b) Tin concentration dependence of the relaxed lattice constants of SnₓGe₁₋ₓ alloy films obtained from high-resolution x-ray analysis of 48 near-strain-free samples (squares). The best fit line yields a function of the form a(x)=5.0×10⁻⁵ x²+0.0074 x+5.6572 (in Å) which is used corroborate the Sn content dependence of the PL spectra obtained from RBS.

FIG. 10 shows room temperature photoluminescence of representative GeSn alloy samples grown on Si substrates and compared to PL plots obtained from pure Ge and Ge(Sn) films grown (“quasi Ge”) directly on Si The wavelength of the peak emission corresponds to the lowest direct band gap in the material.

FIG. 11 shows random and channeled Rutherford backscattering (RBS) spectra of the same material. A weak Sn signal is observed confirming the presence of ˜0.1% Sn % atoms. The high degree of channeling (lower trace) indicates almost-perfect alignment between the film and the underlying Si(100).

FIG. 12 shows XTEM micrographs of a P- and Sn-co-doped film with impurity concentrations of 2×10¹⁹ cm⁻³ and 0.15%, respectively. The defects visible above the interface (top image) are attributed to the relatively high P incorporation. The micrograph also shows a high density of strain at the interface, caused by a periodic array of Lomer misfit dislocations marked by the arrow in the high-resolution image.

FIG. 13 shows room-temperature photoluminescence (PL) spectrum of a Ge(Sn) sample (solid trace), compared to a pure Ge film (circles). The maximum is assigned to direct-gap emission. The weak shoulder at lower energy corresponds to indirect-gap emission. The spectra are normalized to the same peak intensity.

FIG. 14 shows room-temperature PL (left) of a fully relaxed, n-type Ge(Sn) film with a thickness of 1200 nm and a carrier density of about 2×10¹⁹ cm⁻³. Both the direct- and indirect-gap peaks are seen at 1635 and 1865 nm, respectively. The corresponding values for bulk Ge measured using the same procedure are found to be 1600 and 1795 nm. PL spectrum of the same Ge film (right) annealed at 725° C. The overall emission intensity increases dramatically after annealing. The direct/indirect intensity ratio also changes as the thermal expansion induces a finite tensile strain in the film.

FIG. 15 is a schematic representation of the Ge band structure in the near-band-gap region. The arrows represent the transitions corresponding to direct (E₀) and indirect (E_{IND}) gap emission. E_{Fc} is the calculated position of the quasi-Fermi level in the conduction band for a doping concentration n=2×10¹⁹. The top and bottom shaded areas represent electrons and holes, respectively.

FIG. 16 shows room-temperature PL spectra of Ge-like films annealed at 725° C. and containing 0.05% (solid) and 0.3% Sn (dashed) doped with a fixed amount of P (2×10¹⁹ cm⁻³). The peak intensity increases with Sn content and shifts to higher wavelengths.

FIG. 17 shows (Top) XTEM micrograph of the entire Ge(Sn) (i.e., “quasi-Ge”) photodiode structure (about 1 μm thick). The data reveal a virtually defect-free bulk layer and a perfectly smooth surface, indicating that no damage or degradation is caused to the devices by the various fabrication and processing steps. (Bottom) Corresponding AFM image of the material, corroborating the flat surface morphology.

FIG. 18 shows (Top) Current density versus voltage (I-V) graphs obtained from the Sn-doped Ge device and Ge reference samples. In both cases, the mesa sizes are ˜100 μm in diameter. (Bottom) External quantum efficiency (EQE) for a Ge(Sn) (i.e., “quasi-Ge”) heterostructure p-i-n diode measured at zero bias (empty circles), compared with a similar device based on pure Ge layers (full circles). The solid line is a theoretical curve that assumes a collection efficiency of η=0.80 for the optically generated carriers.

FIG. 19 shows room temperature PL signal of n-type Ge_{1-y}Sn_{y} samples as-grown and after rapid thermal annealing. The solid lines show fits with expressions describing direct- and indirect-gap emissions.

FIG. 20 shows room temperature PL from annealed Ge_{0.975}Sn_{0.0250} samples. The weaker signal corresponds to nominally intrinsic material. The relative emission shift is caused by band gap renormalization in the doped sample.

FIG. 21 shows the ratio of direct and indirect emission intensities (from the areas of the peaks used to model the PL in FIG. 19) for annealed doped Ge_{1-y}Sn_{y} samples with doping concentrations near 1.5×10¹⁹. The lines show theoretical simulations using either the compositional dependence of the C-L separation in Ge_{1-y}Sn_{y} alloys or a fixed value as in pure Ge.

### DETAILED DESCRIPTION OF THE INVENTION

The incorporation of Sn is a simple approach for modifying the bandgap of Ge that does not rely on strain and can be accomplished at extremely low growth temperatures. For example, the addition of 0.20% of Sn lowers the band gap of Ge by the same amount as a tensile strain of 0.05% in a pure-Ge sample. Increasing in the Sn concentration to the 1-2% range generates diminishing returns. The absorption edge for Ge₁₋ₓSnₓ has the shape of a step function whereas alloy scattering (as well as the smaller energy of optic phonons) can reduce the carrier saturation velocity which determines the detector's cutoff frequency (see, Colace et al., Lightwave Technology, Journal of 26 (16), 2954 (2008); and Bufler et al., Electron Device Letters, IEEE 18 (6), 264 (1997)).

To investigate this delicate balance, the performance of prototype detectors containing either diluted Ge₁₋ₓSnₓ alloys were compared with pure Ge layers in the Examples below. The results confirm that the Sn-doped Ge leads to devices which display a substantial responsivity enhancement at 1550 nm and, at the same time, improved I-V characteristics relative to prior Ge_{1-y}Sn_{y} pin diodes.

Thus, the Ge(Sn) alloys provided herein can be of the formula, Ge₁₋ₓSnₓ, wherein x is greater than 0 and less than 0.01. In certain embodiments, x is greater than 0.0005. In certain embodiments, x is between about 0.0005 and about 0.003. In certain embodiments, x is between about 0.0005 and about 0.001. In other embodiments, x is between about 0.0006 and about 0.001; or x is between about 0.0005 and about 0.0015; or x is between about 0.0015 and 0.003. The term “about” as used herein means+/−2% of the referenced value.

Such Ge(Sn) alloys can be optionally n-doped or p-doped. In one embodiment, the Ge(Sn) alloys provided herein can be of the formula, Ge₁₋ₓSnₓ, wherein x is less than 0.01 are n-doped. In one embodiment, the Ge(Sn) alloys provided herein can be of the formula, Ge₁₋ₓSnₓ, wherein x is less than 0.01 are p-doped. In one embodiment, the Ge(Sn) alloys provided herein can be of the formula, Ge₁₋ₓSnₓ, wherein x is less than 0.01 are intrinsic alloys. In one embodiment, the Ge(Sn) alloys provided herein can be of the formula, Ge₁₋ₓSnₓ, wherein x is less than 0.01 are doped using both n-type and p-type dopants so as to provide either a partially compensated layer or a fully compensated layer (i.e. highly resistive, or insulating).

Such Ge(Sn) alloys may be formed or processed as described below, to exhibit a rocking scan for the (004) XRD reflection whose full width at half maximum (FWHM) is less than about 200 arcsec; or a FWHM that is less than about 180 arcsec; or a FWHM that is less than about 170 arcsec; or a FWHM that is less than about 160 arcsec; or a FWHM that is less than about 150 arcsec; or a FWHM that is between about 120 arcsec and about 200 arcsec; or a FWHM that is about 140 arcsec. As is familiar to those skilled in the art, a rocking curve measurements is made by doing a θ scan at a fixed 2θ angle, the width of which is inversely proportionally to the dislocation density in the film and is therefore can used as a gauge of the quality of the film.

Further, such Ge(Sn) alloys can be prepared such that the Sn-doping does not essentially change the lattice constant of the Ge(Sn) alloy as compared to an essentially pure Ge sample. For example, the lattice constant of the Ge(Sn) alloys herein are essentially the same as Ge. The phrase “lattice constants are essentially the same as Ge” means that the referenced material has a cubic lattice constant (a) that is 5.658+/−0.005 Å.

Ge(Sn) alloys can be prepared having Sn concentrations in the 10¹⁸-10²⁰ cm⁻³ range on substrates (e.g., Si). For example, the Sn concentrations can be between about 1×10¹⁸ cm⁻³ and about 1×10¹⁹ cm⁻³; about 5×10¹⁸ cm⁻³ and about 1×10¹⁹ cm⁻³; about 1×10¹⁹ cm⁻³ and about 1×10²⁰ cm⁻³; or between about 2×10¹⁹ cm⁻³ and about 1×10²⁰ cm⁻³; or between about 3×10¹⁹ cm⁻³ and about 1×10²⁰ cm⁻³; or between about 4×10¹⁹ cm⁻³ and about 1×10²⁰ cm⁻³; or between about 5×10¹⁹ cm⁻³ and about 1×10²⁰ cm⁻³; or between about 6×10¹⁹ cm⁻³ and about 1×10²⁰ cm⁻³; or between about 8×10¹⁹ cm⁻³ and about 1×10²⁰ cm⁻³; or between about 9×10¹⁹ cm⁻³ and about 1×10²⁰ cm⁻³; or between about 1×10¹⁹ cm⁻³ and about 9×10¹⁹ cm⁻³; or between about 1×10¹⁹ cm⁻³ and about 8×10¹⁹ cm⁻³; or between about 1×10¹⁹ cm⁻³ and about 7×10¹⁹ cm⁻³; or between about 1×10¹⁹ cm⁻³ and about 6×10¹⁹ cm⁻³; or between about 1×10¹⁰ cm⁻³ and about 5×10¹⁹ cm⁻³; or between about 1×10¹⁰ cm⁻³ and about 4×10¹⁹ cm⁻³; or between about 1×10¹⁹ cm⁻³ and about 3×10¹⁹ cm⁻³; or between about 1×10¹⁹ cm⁻³ and about 2×10¹⁹ cm⁻³.

In other examples, the Sn concentrations can be between about 2×10¹⁹ cm⁻³ and about 9×10¹⁹ cm⁻³; or between about 2×10¹⁹ cm⁻³ and about 8×10¹⁹ cm⁻³; or between about 2×10¹⁹ cm⁻³ and about 7×10¹⁹ cm⁻³; or between about 2×10¹⁹ cm⁻³ and about 6×10¹⁹ cm⁻³; or between about 2×10¹⁹ cm⁻³ and about 5×10¹⁹ cm⁻³; or between about 2×10¹⁹ cm⁻³ and about 4×10¹⁹ cm⁻³; or between about 2×10¹⁹ cm⁻³ and about 3×10¹⁹ cm⁻³;

or between about 3×10¹⁹ cm⁻³ and about 9×10¹⁹ cm⁻³; or between about 3×10¹⁹ cm⁻³ and about 8×10¹⁹ cm⁻³; or between about 3×10¹⁹ cm⁻³ and about 7×10¹⁹ cm⁻³; or between about 3×10¹⁹ cm⁻³ and about 6×10¹⁹ cm⁻³; or between about 3×10¹⁹ cm⁻³ and about 5×10¹⁹ cm⁻³; or between about 3×10¹⁹ cm⁻³ and about 4×10¹⁹ cm⁻³;

or between about 4×10¹⁹ cm⁻³ and about 9×10¹⁹ cm⁻³; or between about 4×10¹⁹ cm⁻³ and about 8×10¹⁰ cm⁻³; or between about 4×10¹⁰ cm⁻³ and about 7×10¹⁹ cm⁻³; or between about 4×10¹⁹ cm⁻³ and about 6×10¹⁹ cm⁻³; or between about 4×10¹⁹ cm⁻³ and about 5×10¹⁹ cm⁻³;

or between about 5×10¹⁹ cm⁻³ and about 9×10¹⁹ cm⁻³; or between about 5×10¹⁹ cm⁻³ and about 8×10¹⁹ cm⁻³; or between about 5×10¹⁹ cm⁻³ and about 7×10¹⁹ cm⁻³; or between about 5×10¹⁰ cm⁻³ and about 6×10¹⁰ cm⁻³;

or between about 6×10¹⁹ cm⁻³ and about 9×10¹⁹ cm⁻³; or between about 6×10¹⁹ cm⁻³ and about 8×10¹⁰ cm⁻³; or between about 6×10¹⁰ cm⁻³ and about 7×10¹⁰ cm⁻³;

or between about 7×10¹⁹ cm⁻³ and about 9×10¹⁹ cm⁻³; or between about 7×10¹⁹ cm⁻³ and about 8×10¹⁹ cm⁻³;

or between about 8×10¹⁹ cm⁻³ and about 9×10¹⁹ cm⁻³.

These concentrations are sufficient to engineering improvements in the responsivity of photodetectors operating at 1550 nm. Thus, any of the Ge(Sn) alloys as described above can be used to prepare an assembly as described herein, comprising a substrate and a layer consisting essentially of a Ge(Sn) alloy formed over the substrate.

It should be understood that when a layer is referred to as being “on” or “formed over” another layer or substrate, it can be directly on the layer or substrate, or an intervening layer may also be present. It should also be understood that when a layer is referred to as being “on” or “formed over” another layer or substrate, it may cover the entire layer or substrate, or a portion of the layer or substrate.

It should be further understood that when a layer is referred to as being “directly on” or “directly over” another layer or substrate, the two layers are in direct contact with one another with no intervening layer. It should also be understood that when a layer is referred to as being “directly on” another layer or substrate, it may cover the entire layer or substrate, or a portion of the layer or substrate.

The assembly can comprise a Ge(Sn) layer that is atomically smooth. The phrase “atomically smooth” as used herein means the surface of the referenced layer has a root mean square (RMS) roughness measured by atomic force microscopy (AFM) of less than 1 nm over an area of 20 μm×20 μm. The assembly can also comprise a Ge(Sn) alloy layer is essentially unstrained. The term “essentially unstrained” as used herein means the referenced material has less than about 0.10% strain as measured by high resolution XRD. In certain embodiments, the Ge(Sn) alloy layer is atomically smooth and essentially unstrained.

The Ge(Sn) layer can have a thickness between about 10 nm to at least 3000 nm but there is no limit to the thickness that can be achieved since the material grows strain free. For example, in one embodiment, the thickness can be between about 10 nm and about 900 nm, or about 10 nm and about 800 nm, or about 10 nm and about 700 nm, or about 10 nm and about 600 nm, or about 10 nm and about 500 nm, or about 10 nm and about 400 nm, or about 10 nm and about 300 nm, or about 10 nm and about 200 nm, or about 10 nm and about 100 nm. In other embodiments, the thickness can be between about 25 nm and about 1000 nm, or about 50 nm and about 1000 nm, or about 75 nm and about 1000 nm, or about 100 nm and about 1000 nm, or about 200 nm and about 1000 nm, or about 300 nm and about 1000 nm, or about 400 nm and about 1000 nm, or about 500 nm and about 1000 nm.

In other embodiments, the Ge(Sn) layer can have a thickness between about 0.1 μm to about 10 μm. For example, the Ge(Sn) layer can have a thickness between about 0.2 μm and about 10 μm, or about 0.5 μm and about 10 μm, or about 1.0 μm and about 10 μm, or about 2 μm and about 10 μm, or about 3 μm and about 10 μm, or about 4 μm and about 10 μm, or about 5 μm and about 10 μm. In other examples, the Ge(Sn) layer can have a thickness between about 0.1 μm and about 5 μm, or about 0.5 μm and about 5 μm, or about 1.0 μm and about 5 μm. In yet other examples, the Ge(Sn) layer can have a thickness between about 0.1 μm and about 1 μm, or about 0.2 μm and about 1 μm, or about 0.3 μm and about 1 μm, or about 0.4 μm and about 1 μm, or about 0.5 μm and about 1 μm, or about 0.6 μm and about 1 μm, or about 0.7 μm and about 1 μm, or about 0.8 μm and about 1 μm, or about 0.9 μm and about 1 μm, or about 0.1 μm and about 0.5 μm, or about 0.1 μm and about 0.4 μm, or about 0.1 μm and about 0.3 μm, or about 0.1 μm and about 0.2 μm.

The substrate can be any suitable element having at least one Si surface layer onto which or over which a Ge(Sn) layer can be formed. Examples of substrates include, but are not limited to, Si(100) and silicon-on-insulator (SOI) substrates (e.g., single-faced Si surface layer on SiO₂ or double-faced Si with a first and second Si surface layer each over an embedded SiO₂ layer). As noted above, the use of the small fraction of Sn in this application overcomes the Stranski-Krastanov growth mode of Ge on Si, which typically leads to islanding due to the large lattice constant mismatch between materials. Thus, suitable substrates further include any substrate having a large lattice mismatch with respect to Ge where the S-K growth mode is expected. The Si surface layer itself can consist essentially of Si, such as Si(100). The Si surface layer may also be miscut Si(100). The term “miscut” means that the Si wafer is miscut by about 0.5 to about 8 degrees, or about 1-6 degrees, or about 2-5 degrees. In one particular embodiment, the miscut Si(100) is about 6 degrees miscut.

The Si surface layer can be n-doped Si, p-doped Si, semi-insulating Si, intrinsic Si, compensated Si, provided that the requirements of the first aspect are satisfied as noted above. The term “p-doped” as used herein means atoms have been added to the material (e.g., an alloy) to increase the number of free positive charge carriers. The term “n-doped” as used herein means atoms have been added to the material (e.g., an alloy) to increase the number of free negative charge carriers.

The term “intrinsic semiconductor” as used herein means a semiconductor material in which the concentration of charge carriers is characteristic of the material itself rather than the content of impurities (or dopants).

The term “compensated semiconductor” refers to a semiconductor material in which one type of impurity (or imperfection, for example, a donor atom) partially (or fully) cancels the electrical effects on the other type of impurity (or imperfection, for example, an acceptor atom).

In certain embodiments, the substrate is an intrinsic Si substrate, a compensated Si substrate, a semi-insulating Si substrate, or a silicon-on-insulator (SOI) substrate. In another embodiment, the substrate is a Si(100) wafer, i.e., an n-doped Si(100) wafer, a p-doped Si(100) wafer, semi-insulating Si(100) wafer, a compensated Si(100) wafer, or an intrinsic Si(100) wafer.

The Si surface layer can be of any thickness suitable for a given purpose. For example, the Si surface layer can have a thickness ranging from about 10 nm to about 1 mm. In certain embodiments, the substrate is a Si wafer; thus, the Si surface layer can have the same thickness as that of the Si wafer itself, In such examples, the Si wafer can have a thickness between about 1 μm and about 1 mm, about 1 μm and about 800 μm, or about 100 μm and about 800 μm, or about 200 μm and about 1 mm; or about 200 μm and about 800 μm.

In certain other embodiments, the Si surface layer can be formed over another material, such as an insulator (e.g., SiO₂) on an SOI substrate. In such examples, the Si surface layer can have a thickness between about 10 nm and about 10 μm, or about 10 nm and about 5 μm, or about 10 nm and about 1 μm, or about 10 nm and about 500 nm, or about 10 nm and about 200 nm, or about 10 nm and about 100 nm, or about 100 nm and about 1000 nm, or about 100 nm and about 900 nm, or about 100 nm and about 800 nm, or about 100 nm and about 700 nm, or about 100 nm and about 600 nm, or about 100 nm and about 500 nm or about 100 nm and about 400 nm, or about 100 nm and about 300 nm, or about 100 nm and about 200 nm.

The substrate can be of any size suitable for a given purpose. For example, when the substrate is a Si(100) wafer or a SOI substrate, the substrate can be circular and have a diameter of at least 1 inch, or at least 3 inches, or at least 4 inches, or at least 6 inches. For example, the substrate can have a diameter of about 1 inch to about 12 inches, or about 3 to about 12 inches, or about 6 inches to about 12 inches. In other examples, the substrate can have a diameter of about 8 inches to about 12 inches. In other examples, the substrate can have a diameter of about 100 mm to about 500 mm, or about 100 mm to about 300 mm, or about 100 mm to about 200 mm. In other examples, the substrate is a square Si(100) wafer having dimensions of about 100 mm×100 mm, or about 200×200 mm, or about 150 mm×150 mm, or about 160 mm×160 mm.

The dopant levels of Sn in the Ge(Sn) alloys can be incorporated at temperatures between about 370° C. and about 420° C., to yield layers that can be atomically smooth and/or devoid of threading defects. Such growth conditions are more compatible with CMOS processing than the high growth and processing temperatures required to achieve the same responsivity via tensile strain in pure Ge on Si.

For example, a detailed study of a detector based on a Sn-doped Ge layer with 0.25% (1.1×10²⁰ cm⁻³) Sn range demonstrates the responsivity enhancement and shows much better I-V characteristics than previously fabricated detectors based on Ge_{1-y}Sn_{y} alloys with y=2%, as described in the examples below.

Thus, in the another aspect, method for forming an assembly comprising contacting a surface of a substrate with a vapor comprising Ge₂H₆ and SnD₄ under conditions suitable for forming a Ge(Sn) alloy layer of the formula Ge₁₋ₓSnₓ, layer over the substrate, wherein x is between about 0.0005 and about 0.003. In certain embodiments, the Ge(Sn) alloy layer is formed directly on the substrate.

Forming the Ge(Sn) alloy layer can comprise contacting the Si surface layer with a vapor comprising Ge₂H₆, SnD₄, and an optional dopant source under conditions suitable for depositing the Ge(Sn) alloy layer. Suitable concentrations of Ge₂H₆, SnD₄, and the optional dopant source can be readily determined by one skilled in the art.

In certain embodiments, a molar ratio of about 1:300 to 1:100 SnD₄:Ge₂H₆ can be used for depositing the Ge(Sn) alloy layers herein. Such SnD₄:Ge₂H₆ compositions can be diluted with a carrier gas, such as, but not limited to, hydrogen. In certain embodiments, a mixture of 1:300 to 1:100 Sna₄:Ge₂H₆ can be diluted 10 fold by hydrogen gas.

n-Type Ge(Sn) alloy layers can be prepared by the controlled substitution of P, As, or Sb atoms in the Ge(Sn) alloy lattice according to methods known to those skilled in the art. One example includes, but is not limited to, the use of P(GeH₃)₃ or As(GeH₃)₃, which can furnish structurally and chemically compatible PGe₃ and AsGe₃ molecular cores, respectively (see, Chizmeshya et al., Chem. Mater. 2006, 18, 6266; and US Patent Application Publication No. 2006-0134895-A1, each of which are hereby incorporated by reference in their entirety) can give n-type Ge(Sn) alloy layers. Thus, in one embodiment, the dopant source can comprise of P(GeH₃)₃, As(GeH₃)₃, or mixtures thereof. In one embodiment, the dopant source comprises P(GeH₃)₃ or As(GeH₃)₃. In another embodiment, the dopant source comprises P(GeH₃)₃. In another embodiment, the dopant source comprises As(GeH₃)₃.

p-Type Ge(Sn) alloy layers can be prepared by the controlled substitution of B, Al, or Ga atoms in the Ge(Sn) alloy lattice according to methods known to those skilled in the art. One example includes, but is not limited to, conventional CVD or MBE of SnD₄, Ge₂H₆ and B₂H₆ at low temperatures. Thus, in one embodiment, the dopant source can comprise of B₂H₆.

In another embodiment, the vapor is introduced at a temperature between about 360° C. and 420° C. In another embodiment, the vapor is introduced at a temperature between about 370° C. and 390° C. In another embodiment, the vapor is introduced at a temperature between about 380° C. and 420° C.

In various further embodiments, the vapor is introduced at a partial pressure a pressure between about 1 mTorr and about 1000 mTorr. In one embodiment, the vapor is introduced at a pressure between about 100 mTorr and about 1000 mTorr. In one embodiment, the vapor is introduced at a pressure between about 100 mTorr and about 500 mTorr. In one embodiment, the vapor is introduced at a pressure between about 200 mTorr and about 500 mTorr. In one embodiment, the vapor is introduced at a pressure between about 250 mTorr and about 400 mTorr. In one embodiment, the vapor is introduced at a pressure of about 300 mTorr.

In certain embodiments, the vapor is introduced at a temperature between about 360° C. and 420° C., and a pressure between about 1 mTorr and about 1000 mTorr. In certain embodiments, the vapor is introduced at a temperature between about 360° C. and 420° C., and a pressure between about 100 mTorr and about 500 mTorr.

In certain embodiments, the vapor is introduced at a temperature between about 370° C. and 420° C., and a pressure between about 1 mTorr and about 1000 mTorr. In certain embodiments, the vapor is introduced at a temperature between about 370° C. and 420° C., and a pressure between about 100 mTorr and about 500 mTorr.

In certain other embodiments, the vapor is introduced at a temperature between about 380° C. and 420° C., and a pressure between about 1 mTorr and about 1000 mTorr. In certain embodiments, the vapor is introduced at a temperature between about 380° C. and 420° C., and a pressure between about 100 mTorr and about 500 mTorr.

In certain embodiments, the Ge(Sn) alloy layers can be grown at a rate between about 1 nm/min and about 30 nm/min. For example, the Ge₁₋ₓSnₓ layer can be grown at a rate between about 5 nm/min and about 30 nm/min; or about 10 nm/min and 30 nm/min; or about 15 nm/min and about 30 nm/min; or about 20 nm/min and about 30 nm/min; or about 25 nm/min and about 30 nm/min. In other examples, the Ge(Sn) alloy layer can be grown at a rate between about 1 nm/min and 25 nm/min; or about 1 nm/min and about 20 nm/min; or about 1 nm/min and about 15 nm/min; or about 1 nm/min and about 10 nm/min.

After growth, the Ge(Sn) alloy layer can be annealed, for example, at a temperature of between about 600° C. and about 800° C. For example, the Ge(Sn) alloy layer can be subject to a post-growth Rapid Thermal Annealing treatment. For example, the structure can be heated to a temperature of about 750° C. and held at such temperature for about 1 second to about 10 seconds. The structure can be cycled multiple times between the temperature utilized for deposition (e.g., about 370° C. to about 420° C.) to about 800° C. For example, the structure can be cycled from 1 to 10 times, or 1 to 5 times, or 1 to 3 times. In one embodiment, the first doped Ge(Sn) alloy layer is rapid thermal annealed to a temperature between about 370° C. and about 725° C. at least two times. In one embodiment, the second doped Ge(Sn) alloy layer is rapid thermal annealed to a temperature between about 370° C. and about 725° C. at least two times. In another embodiment, the first and second doped Ge₁₋ₓSnₓ layers are rapid thermal annealed to a temperature between about 370° C. and about 725° C. at least two times.

Optionally, and in other embodiments, a second Ge(Sn) alloy layer of the formula Ge₁₋ₓSnₓ can be grown over or directly over the preceding Ge(Sn) alloy; such second Ge(Sn) alloy layer may be, for example, a formed as doped Ge(Sn) alloy layer over the first Ge(Sn) alloy layer.

In another aspect, the present disclosure provides photodiodes comprising a doped substrate having a surface layer; an intrinsic Ge(Sn) alloy layer formed directly over the Si surface layer; and a second Ge(Sn) alloy layer directly over the intrinsic Ge(Sn) alloy layer, wherein one of the substrate surface layer and the second Ge(Sn) alloy layer is p-doped and the other is n-doped.

In certain embodiments, the second Ge(Sn) alloy layer of the formula Ge₁₋ₓSnₓ layer has an x value less than the intrinsic Ge(Sn) alloy layer. For example, in one embodiment, the intrinsic Ge(Sn) alloy layer of the formula Ge₁₋ₓSnₓ layer has an x value between 0.001 and 0.003; and the second Ge(Sn) alloy layer of the formula Ge₁₋ₓSnₓ has an x value between 0.0005 and 0.001.

In another embodiment, the intrinsic Ge(Sn) alloy layer of the formula Ge₁₋ₓSnₓ has an x value of about 0.0005; and the second Ge(Sn) alloy layer of the formula Ge₁₋ₓSnₓ has an x value between 0.001 and 0.003.

In another embodiment, the intrinsic Ge(Sn) alloy layer of the formula Ge₁₋ₓSnₓ has an x value of about 0.0025 (about 1.1×10²⁰ cm⁻³ Sn) and the second Ge(Sn) alloy layer of the formula Ge₁₋ₓSnₓ has an x of about 0.0003 (about 1.0×10¹⁹ cm⁻³ Sn).

The substrates in the instant photodiodes can be any of the substrates as discussed above for the assemblies of the invention.

The second Ge(Sn) alloy layer can have a thickness between about 10 nm to about 1000 nm. For example, in one embodiment, the thickness can be between about 10 nm and about 900 nm, or about 10 nm and about 800 nm, or about 10 nm and about 700 nm, or about 10 nm and about 600 nm, or about 10 nm and about 500 nm, or about 10 nm and about 400 nm, or about 10 nm and about 300 nm, or about 10 nm and about 200 nm, or about 10 nm and about 100 nm. In other examples, the thickness can be between about 25 nm and about 1000 nm, or about 50 nm and about 1000 nm, or about 75 nm and about 1000 nm, or about 100 nm and about 1000 nm, or about 200 nm and about 1000 nm, or about 300 nm and about 1000 nm, or about 400 nm and about 1000 nm, or about 500 nm and about 1000 nm.

The intrinsic Ge(Sn) alloy layer can have a thickness between about 0.1 μm to about 10 μm. For example, the intrinsic Ge₁₋ₓSnₓ layer can have a thickness between about 0.2 μm and about 10 μm, or about 0.5 μm and about 10 μm, or about 1.0 μm and about 10 μm, or about 2 μm and about 10 μm, or about 3 μm and about 10 μm, or about 4 μm and about 10 μm, or about 5 μm and about 10 μm. In other examples, the Ge₁₋ₓSn layer can have a thickness between about 0.1 μm and about 5 μm, or about 0.5 μm and about 5 μm, or about 1.0 μm and about 5 μm. In yet other examples, the intrinsic Ge₁₋ₓSnₓ layer can have a thickness between about 0.1 μm and about 1 μm, or about 0.2 μm and about 1 μm, or about 0.3 μm and about 1 μm, or about 0.4 μm and about 1 μm, or about 0.5 μm and about 1 μm, or about 0.6 μm and about 1 μm, or about 0.7 μm and about 1 μm, or about 0.8 μm and about 1 μm, or about 0.9 μm and about 1 μm, or about 0.1 μm and about 0.5 μm, or about 0.1 μm and about 0.4 μm, or about 0.1 μm and about 0.3 μm, or about 0.1 μm and about 0.2 μm.

In another embodiment, the intrinsic Ge(Sn) alloy layer can have a thickness between about 0.5 μm and about 5 μm; and second Ge(Sn) alloy layer can have a thickness between about 10 nm to about 1000 nm. In one embodiment, the intrinsic Ge(Sn) alloy layer can have a thickness between about 0.5 μm and about 5 μm; and second Ge(Sn) alloy layer can have a thickness between about 10 nm and about 200 nm.

In another embodiment, the intrinsic Ge(Sn) alloy layer can have a thickness between about 0.1 μm and about 1.0 μm; and the second Ge(Sn) alloy layer can have a thickness between about 10 nm to about 1000 nm. In another embodiment, the intrinsic Ge(Sn) alloy layer can have a thickness between about 0.1 μm and about 1.0 μm; and the second Ge(Sn) alloy layer can have a thickness between about 10 nm and about 200 nm.

When the preceding Ge(Sn) alloy layers are n-doped, then they can comprise P, As, or mixtures thereof. In one embodiment, n-doped Ge(Sn) alloy layer comprise P. In one embodiment, n-doped Ge(Sn) alloy layer comprises As. When the preceding Ge(Sn) alloy layers are p-doped, then they can comprise B or Al.

The second Ge(Sn) alloy layer can have an active carrier concentration of about 10¹⁷ cm⁻³ to about 10²⁰ cm⁻³. In one embodiment, the second Ge(Sn) alloy layer has an active carrier concentration of about 10¹⁸ cm⁻³ to about 10²⁰ cm⁻³. In another embodiment, the second Ge(Sn) alloy layer has an active carrier concentration of about 10¹⁷ cm⁻³ to about 10²⁰ cm⁻³. In another embodiment, the second Ge(Sn) alloy layer has an active carrier concentration of about 10¹⁸ cm⁻³ to about 10²⁰ cm⁻³.

The Si surface layer can have an active carrier concentration of about 10¹⁷ cm⁻³ to about 10²⁰ cm⁻³. In one embodiment, the Si surface layer has an active carrier concentration of about 10¹⁸ cm⁻³ to about 10²⁰ cm⁻³. In another embodiment, the Si surface layer has an active carrier concentration of about 10¹⁷ cm⁻³ to about 10²⁰ cm⁻³. In another embodiment, the Si surface layer has an active carrier concentration of about 10¹⁸ cm⁻³ to about 10²⁰ cm⁻³.

One or both the Ge(Sn) alloy layers can be fully relaxed as is understood by one in the art. In one embodiment, the intrinsic Ge(Sn) alloy layer is relaxed. In another embodiment, the intrinsic and the second Ge(Sn) alloy layers are each relaxed.

The preceding photodiodes can further comprising an insulating layer formed over the second Ge(Sn) alloy. In one embodiment, the insulating layer is SiO₂. Each photodiode can further comprise at least one first electrode in electrical contact with the Si surface layer. When the at least one first electrode is in contact with the Si surface layer and the substrate is a Si wafer, then the electrode can either be in electrical contact via the front surface (the surface onto which the intrinsic Ge(Sn) alloy layer is formed) or the back face (the opposing face) of the wafer.

Further, each photodiode can further comprise at least one second electrode in electrical contact with the second Ge(Sn) alloy layer. The first and second electrode can independently comprise Ti, Cr, Ni, Pd, Pt, Au, Ag, Al, Cu, or mixtures thereof. In one embodiment, each electrode comprises an adhesion layer comprising Cr or Ti, and a contact layer comprising Pt, Au, Ag, Al, or Cu.

The photodiodes any of the preceding embodiments may further comprise one or more light trapping features such as, but not limited to, texture and/or a surface reflector.

The intrinsic Ge(Sn) alloy layer can be formed by contacting the surface layer with a second vapor comprising or consisting essentially of Ge₂H₆ and SnD₄ under conditions suitable for depositing the intrinsic Ge(Sn) alloy layer. Particular embodiments for the method for forming the intrinsic Ge(Sn) alloy layer are as described above for preparation of the preceding assemblies.

Forming the second doped Ge(Sn) alloy layer can comprise contacting the intrinsic Ge(Sn) alloy layer with a third vapor comprising Ge₂H₆, SnD₄, and a second dopant source under conditions suitable for depositing the second doped Ge₁₋ₓSnₓ layer. Particular embodiments for the method for forming the second Ge(Sn) alloy layer are as described above for preparation of the preceding assemblies.

In one embodiment, each of the second and third vapors are introduced at a temperature between about 360° C. and about 410° C., and a pressure between about 100 mTorr and about 500 mTorr.

In one embodiment, each of the second and third vapors are introduced at a temperature between about 370° C. and about 390° C., and a pressure between about 100 mTorr and about 500 mTorr.

In another embodiment, each of the second and third vapors are introduced at a temperature between about 380° C. and about 410° C., and a pressure between about 100 mTorr and about 500 mTorr.

In another embodiment, each of the second and third vapors are introduced at a temperature between about 370° C. and about 390° C. and a pressure between about 100 mTorr and about 500 mTorr, where the second dopant source comprises P(GeH₃)₃.

In another embodiment, each of the second and third vapors are introduced at a temperature between about 370° C. and about 390° C. and a pressure between about 100 mTorr and about 500 mTorr, where the second dopant source comprises As(GeH₃)₃.

In another embodiment, each of the second and third vapors are introduced at a temperature between about 370° C. and about 390° C. and a pressure between about 100 mTorr and about 500 mTorr, where the second dopant source comprises B₂H₆.

In a further embodiment, any of the preceding embodiment scan further comprise forming an insulating layer, for example, SiO₂, over the second doped Ge(Sn) alloy layer. The insulating layer can have a thickness between about 10 nm to about 1000 nm. For example, the insulating layer can have a thickness between about 10 nm and about 900 nm, or about 10 nm and about 800 nm, or about 10 nm and about 700 nm, or about 10 nm and about 600 nm, or about 10 nm and about 500 nm, or about 10 nm and about 400 nm, or about 10 nm and about 300 nm, or about 10 nm and about 200 nm, or about 10 nm and about 100 nm.

In other examples, the insulating layer can each have a thickness between about 25 nm and about 1000 nm, or about 50 nm and about 1000 nm, or about 75 nm and about 1000 nm, or about 100 nm and about 1000 nm, or about 100 nm and about 500 nm, or about 100 nm and about 300 nm, or about 100 nm and about 200 nm.

The gaseous precursors (e.g., the second and third vapors) for deposition of the various Ge(Sn) alloy layers can be deposited by any suitable technique, including but not limited to gas source molecular beam epitaxy, chemical vapor deposition, plasma enhanced chemical vapor deposition, laser assisted chemical vapor deposition, and atomic layer deposition. In one embodiment, each of the Ge(Sn) alloy layers can be formed by chemical vapor deposition.

In certain embodiments, the doping of the second doped Ge(Sn) alloy layer is not provided by ion implantation.

Additionally, in other aspects, the invention provides additional photodiodes, avalanche photodetectors comprising the photodiodes as described herein; photonic circuit elements comprising a photodiode as described herein, and a waveguiding structure in optical communication with the photodiode; and arrays comprising a plurality of photodiodes as described herein, arranged in a predetermined arrangement.

Photodiodes

In another aspect, the present disclosure provides photodiodes comprising a substrate having a surface layer; an optional first Ge(Sn) alloy layer comprising an alloy described here formed directly over the surface layer; an intrinsic Ge(Sn) alloy layer comprising an alloy described herein formed directly over either the Si surface layer or, when present, the first Ge(Sn) alloy layer; and a second Ge(Sn) alloy layer comprising an alloy described herein formed directly over the intrinsic Ge(Sn) alloy layer, wherein one of (i) the surface layer or the first Ge(Sn) alloy layer and (ii) the second Ge(Sn) alloy layer is p-doped and the other of (i) and (ii) is n-doped, provided that when the surface layer is doped and the first Ge(Sn) alloy layer is present, then the surface layer and the first Ge(Sn) alloy layer are both n-doped or are both p-doped.

The optional first Ge(Sn) alloy, when present, can have a thickness between about 10 nm to about 1000 nm. For example, in one embodiment, the thickness can be between about 10 nm and about 900 nm, or about 10 nm and about 800 nm, or about 10 nm and about 700 nm, or about 10 nm and about 600 nm, or about 10 nm and about 500 nm, or about 10 nm and about 400 nm, or about 10 nm and about 300 nm, or about 10 nm and about 200 nm, or about 10 nm and about 100 nm. In other embodiments, the thickness can be between about 25 nm and about 1000 nm, or about 50 nm and about 1000 nm, or about 75 nm and about 1000 nm, or about 100 nm and about 1000 nm, or about 200 nm and about 1000 nm, or about 300 nm and about 1000 nm, or about 400 nm and about 1000 nm, or about 500 nm and about 1000 nm.

In a further embodiment, the first and second Ge(Sn) alloy layers can each have a thickness between about 10 nm to about 1000 nm. For example, the each can have a thickness between about 10 nm and about 900 nm, or about 10 nm and about 800 nm, or about 10 nm and about 700 nm, or about 10 nm and about 600 nm, or about 10 nm and about 500 nm, or about 10 nm and about 400 nm, or about 10 nm and about 300 nm, or about 10 nm and about 200 nm, or about 10 nm and about 100 nm. In other examples, the first and second Ge₁₋ₓSnₓ layers can each have a thickness between about 25 nm and about 1000 nm, or about 50 nm and about 1000 nm, or about 75 nm and about 1000 nm, or about 100 nm and about 1000 nm, or about 200 nm and about 1000 nm, or about 300 nm and about 1000 nm, or about 400 nm and about 1000 nm, or about 500 nm and about 1000 nm.

In another embodiment, the intrinsic Ge(Sn) alloy layer can have a thickness between about 0.5 μm and about 5 μm; and the first and second Ge(Sn) alloy layers can each have a thickness between about 10 nm to about 1000 nm. In one embodiment, the intrinsic Ge(Sn) alloy layer can have a thickness between about 0.5 μm and about 5 μm; and the first and second Ge(Sn) alloy layers can each have a thickness between about 10 nm and about 200 nm.

In another embodiment, the intrinsic Ge(Sn) alloy layer can have a thickness between about 0.1 μm and about 1.0 μm; and the first and second Ge(Sn) alloy layers can each have a thickness between about 10 nm to about 1000 nm. In another embodiment, the intrinsic Ge(Sn) alloy layer can have a thickness between about 0.1 μm and about 1.0 μm; and the first and second Ge(Sn) alloy layers can each have a thickness between about 10 nm and about 200 nm.

The first Ge(Sn) alloy layer can have an active carrier concentration of about 10¹⁷ cm⁻³ to about 10²⁰ cm⁻³. In one embodiment, the first Ge(Sn) alloy layer has an active carrier concentration of about 10¹⁸ cm⁻³ to about 10²⁰ cm⁻³. In another embodiment, the first Ge(Sn) alloy layer has an active carrier concentration of about 10¹⁷ cm⁻³ to about 10²⁰ cm⁻³. In another embodiment, the first Ge(Sn) alloy layer has an active carrier concentration of about 10¹⁸ cm⁻³ to about 10²⁰ cm⁻³.

At least one, two, or all three of the Ge(Sn) alloy layers can be fully relaxed as is understood by one in the art. In one embodiment, the first Ge(Sn) alloy layer is relaxed. In another embodiment, the first Ge(Sn) alloy layer and the intrinsic Ge(Sn) alloy layer are both relaxed. In another embodiment, the first, second, and intrinsic Ge(Sn) alloy layers are each relaxed. In another embodiment, the first and second Ge(Sn) alloy layers are each relaxed. In another embodiment, the intrinsic and the second Ge(Sn) alloy layers are each relaxed.

The first Ge(Sn) alloy layer, when preset, can be formed by contacting the surface layer with a first vapor comprising Ge₂H₆ and SnD₄ and an optional first dopant source, under conditions suitable for depositing the first Ge(Sn) alloy. Particular embodiments for the method for forming the first Ge(Sn) alloy layer are as described above for preparation of the preceding assemblies.

The intrinsic Ge(Sn) alloy layer can be formed by contacting the surface layer or the first doped Ge(Sn) alloy, when present, with a second vapor comprising or consisting essentially of Ge₂H₆ and SnD₄ under conditions suitable for depositing the intrinsic Ge(Sn) alloy layer. Particular embodiments for the method for forming the intrinsic Ge(Sn) alloy layer are as described above for preparation of the preceding assemblies.

In one embodiment, each of the first vapor, when the first doped Ge₁₋ₓSnₓ layer is formed, and the second and third vapors are introduced at a temperature between about 360° C. and about 420° C., and a pressure between about 100 mTorr and about 500 mTorr.

In another embodiment, each of the first vapor, when the first doped Ge₁₋ₓSnₓ layer is formed, and the second and third vapors are introduced at a temperature between about 360° C. and about 420° C., and a pressure between about 100 mTorr and about 500 mTorr.

In one embodiment, each of the first vapor, when the first doped Ge(Sn) alloy layer is formed, and the second and third vapors are introduced at a temperature between about 370° C. and about 390° C., and a pressure between about 100 mTorr and about 500 mTorr.

In another embodiment, each of the first vapor, when the first doped Ge(Sn) alloy layer is formed, and the second and third vapors are introduced at a temperature between about 380° C. and about 420° C., and a pressure between about 100 mTorr and about 500 mTorr.

In one embodiment, each of the first vapor, when the first doped Ge(Sn) alloy layer is formed, and the second and third vapors are introduced at a temperature between about 370° C. and about 390° C., and a pressure between about 100 mTorr and about 500 mTorr, where the first dopant source comprises B₂H₆ and the second dopant source comprises P(GeH₃)₃ or As(GeH₃)₃.

In another embodiment, each of the first vapor, when the first doped Ge(Sn) alloy layer is formed, and the second and third vapors are introduced at a temperature between about 370° C. and about 390° C. and a pressure between about 100 mTorr and about 500 mTorr, where the first dopant source comprises B₂H₆ and the second dopant source comprises P(GeH₃)₃.

In another embodiment, each of the first vapor, when the first doped Ge(Sn) alloy layer is formed, and the second and third vapors are introduced at a temperature between about 370° C. and about 390° C. and a pressure between about 100 mTorr and about 500 mTorr, where the first dopant source comprises B₂H₆ and the second dopant source comprises As(GeH₃)₃.

In another embodiment, each of the first vapor, when the first doped Ge(Sn) alloy layer is formed, and the second and third vapors are introduced at a temperature between about 370° C. and about 390° C. and a pressure between about 100 mTorr and about 500 mTorr, where the first dopant source comprises P(GeH₃)₃ or As(GeH₃)₃ and the second dopant source comprises B₂H₆.

The gaseous precursors (first, second, and third vapors) for deposition of the various Ge(Sn) alloy layers can be deposited by any suitable technique, including but not limited to gas source molecular beam epitaxy, chemical vapor deposition, plasma enhanced chemical vapor deposition, laser assisted chemical vapor deposition, and atomic layer deposition. In one embodiment, each of the Ge(Sn) alloy layers can be formed by chemical vapor deposition or molecular beam epitaxy.

In certain embodiments, the first doped Ge(Sn) alloy layer, when present, the second doped Ge(Sn) alloy layer and the intrinsic Ge(Sn) alloy layer are each independently formed by molecular beam epitaxy or chemical vapor deposition.

In certain embodiments, the doping of the first doped Ge(Sn) alloy layer and the second doped Ge(Sn) alloy layer are not provided by ion implantation.

The preceding photodiodes can further comprising an insulating layer formed over the second Ge(Sn) alloy. In one embodiment, the insulating layer is SiO₂. Each photodiode can further comprise at least one first electrode in electrical contact with the Si surface layer or the first Ge(Sn) alloy layer. When the at least one first electrode is in contact with the Si surface layer and the substrate is a Si wafer, then the electrode can either be in electrical contact via the front surface (the surface onto which the intrinsic Ge(Sn) alloy layer is formed) or the back face (the opposing face) of the wafer.

Photodetectors

The avalanche photodetectors can further comprise a multiplication layer disposed between the Si surface layer and the first Ge(Sn) layer, when present, or the intrinsic Ge(Sn) layer, when present; or disposed over the second Ge(Sn) layer. Further, an optional charge layer can contact the multiplication layer and can be disposed between the multiplication layer and a Ge(Sn) layer that it contacts. The multiplication layer can receive the primary charge carriers from one of the Ge(Sn) layers and responsively produces the secondary charge carriers. The charge layer can act to keep the electric field in the multiplication layer high, while keeping the electric field in the Ge(Sn) layers low. Further, an electrical bias source can apply a bias voltage across the avalanche photodetectors structure.

Photonic Circuits

Photonic circuit elements may comprise a photodiode as described above, or any embodiment thereof, and a waveguiding structure in optical communication with the photodiode. Such waveguiding structures may be in communication with a light emitting diode. The waveguiding structure can be formed, for example by a SiOₓN_{y} or Si₃N₄ layer between two SiO₂ cladding layers, where one of the SiO₂ cladding layers is in contact with the preceding insulating layer or both of the SiO₂ cladding layers forms part of the preceding insulating layer. See, for example, Yamada et al., Thin Solid Films 2006, 508, 399-401, which is hereby incorporated by reference in its entirety.

Detector Arrays

Detector arrays may be prepared comprising a plurality of photodiode elements as described above, or any embodiment thereof, in a predetermined arrangement. For example, the photodiode elements can be arranged in a 2-D grid. In another example, the photodiode elements can be arranged in a line.

In one embodiment, the detector arrays comprise a plurality of p-i-n photodiode elements according the first aspect (i.e., comprising the intrinsic GeSn layer) and any of the preceding embodiments thereof in a predetermined arrangement.

In general, such arrays can be formed across a substrate as described below. An array of detectors can be fabricated on a single substrate wafer. To form, for example, a focal-plane array, one could design the detectors appropriately (size, spacing, electrical connections, as is known to one skilled in the art), process the entire wafer, and then separate the arrays by cleaving, dicing, or sawing of the wafer, as is known in the art, to separate the individual arrays.

Standard lithography can be used employed to delineate the appropriate patterns thereon, for example, mesa patterns using a positive photoresist, such as, but not limited to, AZ 3312 photoresist.

Reactive ion etching (RIE) can then be used to create patterned mesas. For example, BCl₃ gas can be used as the reactant to generate plasma at flow rate of 8 sccm, pressure of 50 mTorr and RF power setting of 50 W, and an etch rate of 50 nm/min. The mesas produced can have well-defined shapes, sharp edges, and flat, residue-free sidewalls.

The photoresist can be removed as is familiar to one skilled in the art, for example, with acetone, and a SiO₂ layer can be deposited on top of the mesas, which serves as an antireflective and passivation coating. The SiO₂ layer can have a thickness between about 100 nm and about 1000 nm. For example, the SiO₂ layer thickness can be between about 200 nm and about 1000 nm, or about 200 nm and about 750 nm, or about 300 nm and about 750 nm, or about 300 nm and about 600 nm, or about 400 nm and about 600 nm, or about 400 nm and 500 nm.

In certain embodiments, the methods comprise forming at least one first electrode in electrical contact with the Si surface layer. In certain embodiments, the methods comprise forming at least one second electrode in electrical contact with the second doped Ge₁₋ₓSnₓ layer. Such contacts can be formed either on the front side of the devices or the back side.

For example, metal contact (electrode) areas can be defined via a lift-off process (e.g., etching and filling) as is familiar to one skilled in the art, for example, by using a negative photoresist such as, but not limited to; AZ 4330 photoresist, which is suitable for this purpose due to the negative profile of the sidewall. In such instances, when first doped Ge₁₋ₓSnₓ layer is present, the first doped layer should be thick enough to stop the etching process within the layer to provide contact. Such thickness can be determined by one skilled in the art.

Metal contacts (e.g., the first and/or second electrodes) can be deposited, using e-beam evaporation, consisting of an adhesion layer followed by a metal film. The first and second electrode can independently comprise Ti, Cr, Ni, Pd, Pt, Au, Ag, Al, Cu, or mixtures thereof. Suitable adhesion layers include, but are not limited to Cr or Ti. Metal films include, but are not limited to Pt, Au, Ag, Al, or Cu. After metal lift-off, the samples can be cleaned in an oxygen plasma.

Lasers

In other embodiments, the Ge(Sn) alloys of the invention can be used in to form Ge-on-Si lasers. For example, the Ge layers used in the design described in Liu et al. Optics Lett. 2010, 35, 679, which is hereby incorporated by reference in its entirety, may be substituted for the Ge(Sn) alloys of the invention. The small amounts of Sn in the instant alloys may improve the performance of such laser structures since the addition of Sn monotonically reduces the separation between the direct and indirect minima in the conduction band of Ge.

### EXAMPLES

### Example 1

### Growth of Sn Doped Ge by UHV CVD

We have developed fabrication of highly crystalline, and essentially strain-free Ge films with a flat surface via SnD₄ assisted deposition of pure digermane diluted in H₂ (about 30%) by volume. These studies are conducted via CVD directly on Si (100) at unprecedented low-temperature conditions of 390° C. yielding layer thicknesses of about 0.5 to 1.0 μm at a growth rate of about 20 nm/min. The initial characterizations of the as grown Ge layers by XRD, RBS, AFM and Nomarski microscopy indicate that the structural and morphological properties are comparable to those of their counterparts produced via our newly developed gas source MBE approach which has been found to produce device quality materials with record low dislocation densities and optical/electrical response similar or better than state of the art. In particular the RBS ion channeling and the AFM/Nomarski images show extremely low chi minimum values and flat surfaces, respectively. The samples are subjected to RTA processing consisting of three cycles of heating to 680° C. for 10 seconds to improve crystallinity by reducing mosaic spread and threading defect densities as well as eliminating residual strains. One figure of merit is the full width at half maximum (FWHM) of the 004 on axis Bragg peak which in this case is markedly sharpened and intensified giving values as low as 300 arc seconds which is on par to the best Ge on Si materials known to date. After annealing the film surface remains flat (RMS about 1 nm) and layer RBS channeling is dramatically improved with final x minimum values in the range of 5-10% which is close to the experimental limit for bulk Si wafers. Since the Sn content in these samples is below the RBS detection limit we conducted SIMS elemental analysis of the annealed layers which revealed a highly homogeneous profile of the element throughout the crystal at concentration of 1-2×10¹⁹ atoms/cm³. This indicates that under the growth conditions employed here the Sn does not function as a surfactant but is incorporated as a fully substitutional atom in the average diamond lattice of the material, as expected. In prior work we show that there is an inverse relationship between the growth temperature and the level of Sn incorporation into the Ge lattice via this CVD approach. For example, diluted alloys containing 0.6-3.0 Sn % are produced at 380-350° C. as discussed below. Accordingly, the doping 10¹⁹/cm³ levels found here follow this latter trend and produce a true random solid solution with intrinsic physical and chemical properties nearly identical to those of the parent Ge material including its thermal stability. Perhaps most importantly this CVD approach represents a significant advancement over the previously discussed gas source MBE method because it enables the fabrication of high quality material at industrial scale growth rates on multiple substrates during a single run. The latter also implies significant cost reductions since the same amount of chemicals are used in both the batch reactor and the single wafer format tool.

### Example 2

### Growth of Ge_{1-y}Sn_{y} alloys (y=0.006-0.03)

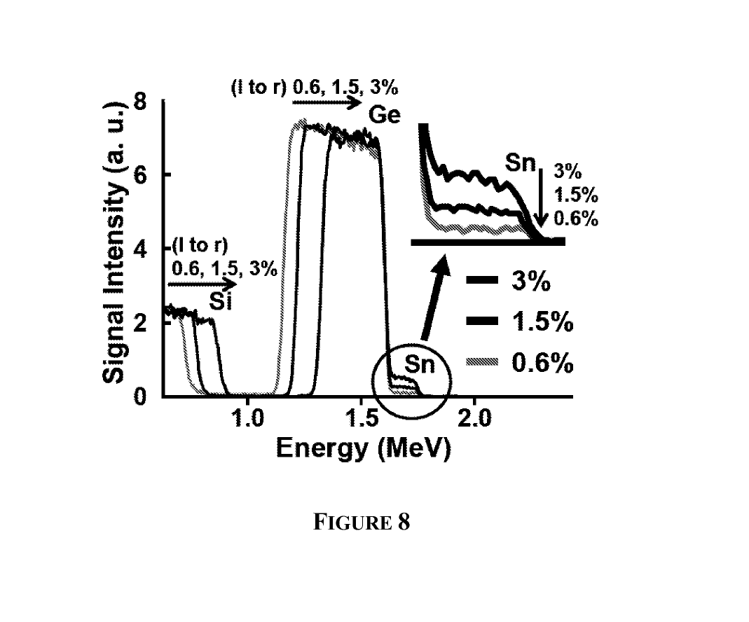

Using the same UHV-CVD reactor we next undertook the growth of the Ge_{1-y}Sn_{y} (0.6<y<3%) alloys on 2″ in-diameter p-type Si(100) wafers with resistivities of 10³ Ωcm. In these experiments as in the above Ge on Si case the chemically pre-cleaned platforms were dipped in 5% HF solution to hydrogen-passivate their surface prior to growth. Samples with nominal Sn fractions of 0.6, 1.5 and 3% were produced via reactions of Ge₂H₆ and SnD₄ at 300 mTorr and at temperatures of 380, 360 and 350° C., respectively. The Sn fraction in the alloy was precisely controlled in the 0.6-3% range by increasing the amount of SnD₄ in the gaseous mixture while systematically decreasing the deposition temperature to ensure full Sn substitution. As the Sn content is increased in these alloys a slightly milder post growth RTA step, consisting of three cycles at 650-750° C. for 5-10 seconds (depending on composition), was employed to reduce the levels of threading defects and ensure that the material is devoid of any residual compressive strains which are typically 0.2% in the as deposited materials under these processing conditions. An additional heat treatment under hydrogen was adopted to passivate surface states as well as point defects and possible dislocation boundaries for the purpose of enhancing the PL signal particularly for films with the lower Sn contents below 2%. We note that the same treatment was applied to the CVD Ge samples above prior to PL characterizations All samples were transferred into an annealing tube-furnace, pumped at 10⁻⁴ Torr and purged at room temperature with 20% ultra high purity H₂ diluted in argon. The pump/purge cycle was repeated three times after which the wafers were inserted into the hot zone and heated at 830-650° C. for 30 minutes under a constant stream of H₂/Ar at ambient pressure. We note that all samples excluding the 3% Sn material were annealed at the higher temperature regime 830-750° C. and as we discuss below the process increases their PL signal by an order of magnitude relative to that prior to treatment. For the 3% sample we find that a lower annealing temperature of 650° C. needed to avoid degradation may not be sufficient to produce the desired passivation and as a result the PL intensity only increased by 50% with respect to the original RTA counterpart. All samples were subsequently characterized for morphology, structure, crystallinity and composition by high resolution x-ray diffraction (HR-XRD), Rutherford back scattering (RBS), secondary ion mass spectroscopy (SIMS) and spectroscopic ellipsometry. XRD reciprocal space maps of the (224) reflections and on-axis (004) plots indicated that the annealed layers exhibited a nominal tensile strain of 0.12-0.15% due to thermal expansion mismatches between the films and the Si substrate. The full width at half maximum (FWHM) of the (004) rocking curve ranged from about 250-550 arc-seconds with increasing Sn content from 0.1 to 3%, indicating a high degree of crystalline perfection and significantly reduced densities of threading dislocations in the epilayer with respect to the as grown materials. RBS was routinely used to measure the Sn content in the range of 0.6-3% and corroborate the single-phase character of the materials using ion channeling. I all cases the ratio of the aligned over the random peak heights (x minimum) was identical for the Ge and Sn signals in the spectra indicating full substituionality of the Sn atoms within the average Ge diamond cubic network as shown in FIG. 8 for representative sample containing the aforementioned compositions.

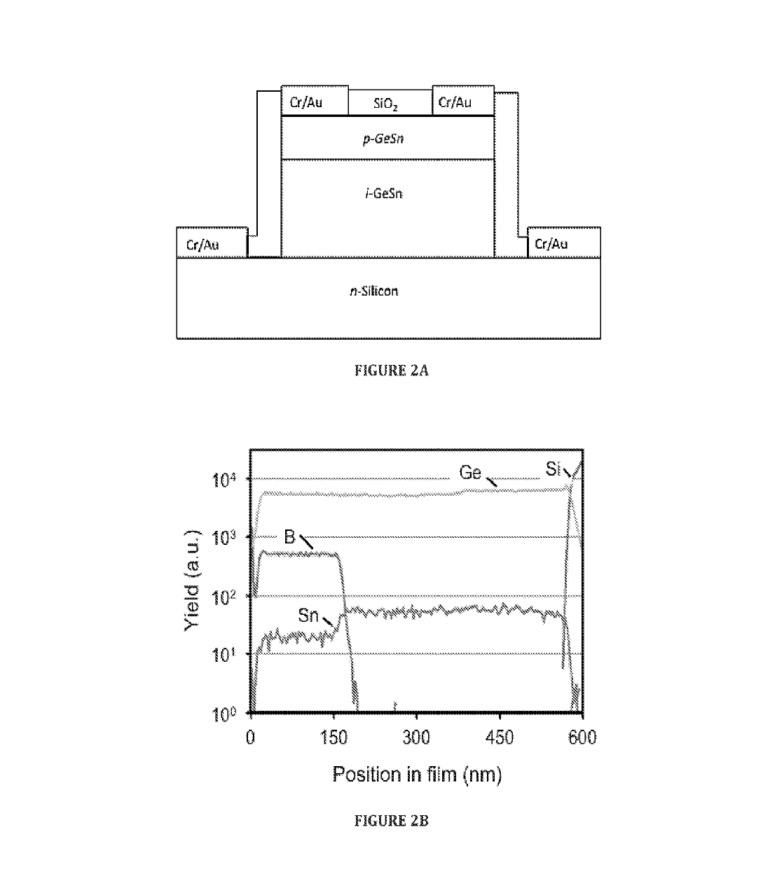

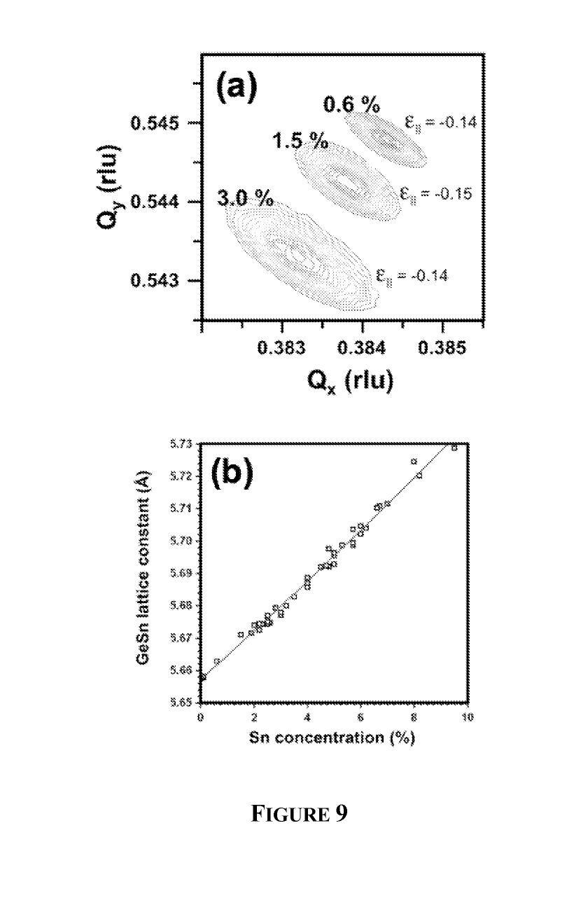

The relaxed lattice parameters (aₒ) of 5.6616, 5.6675 and 5.6782 Å obtained by XRD (see FIG. 2) are consistent with the calculated values of alloys containing 0.6, 1.5% and 3% Sn, as expected. The lattice constant of the 10¹⁹/cm³ Sn samples appeared nearly identical to that of elemental Ge, as expected due to the broadness of both 004 and 224 peaks and lack of resolution to distinguish them from those of bulk Ge. The low amount of Sn in this case could not be measured by RBS and was determined instead by SIMS depth profiles which showed a uniform distribution of the elemental content throughout the layer. For all samples heated above 800° C. a minimal amount of Si out diffusion in the range of 10¹⁹ atoms/cm³ was observed in the vicinity of the interface region in the SIMS spectra. It is important to note that this behavior was not seen in the 3 Sn % materials due to their low processing temperatures as corroborated by XRD on axis plots which showed a perfectly symmetrical 004 peak as shown in FIG. 9a. For all samples film thicknesses spanning about 0.45 to 0.7 μm were measured with ellipsometry and were found to be in close agreement with those obtained by RBS (and cross-sectional transmission electron microscopy (XTEM)) analyses yielding average growth rates of 14-17 nm/min. In this study we chose a minimum threshold thickness of approximately 0.5 μm to mitigate the impact of the edge dislocations at the GeSn/Si(100) interface on the layer optical response as is evident from the observation of the PL signal for the first time in GeSn materials

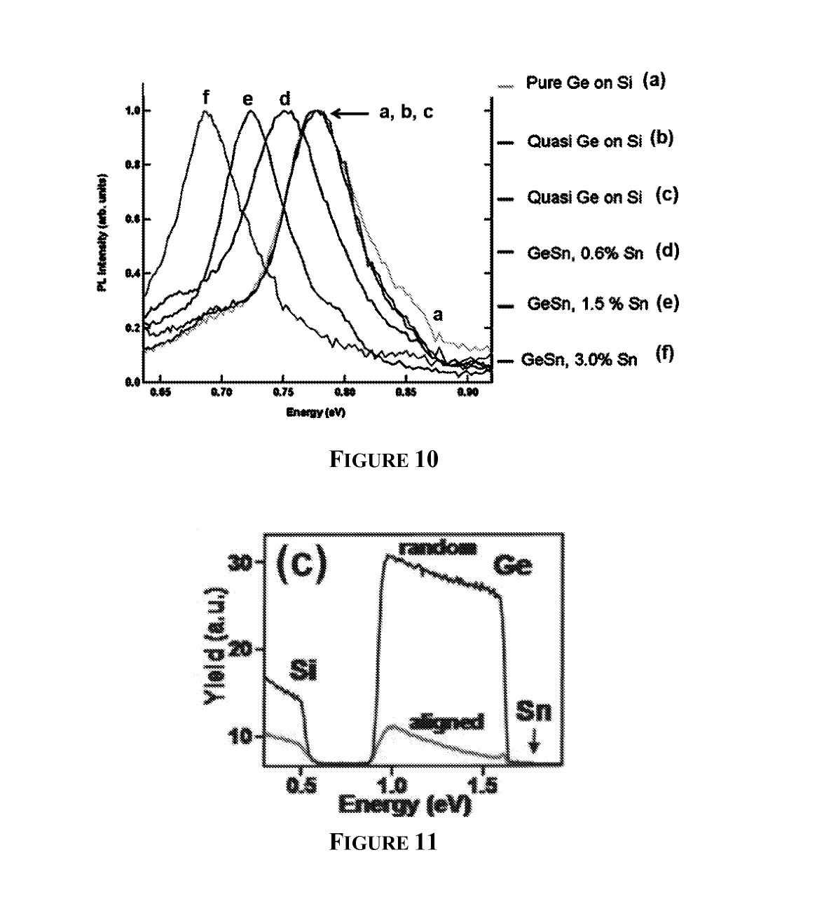

We believe that the observation of direct-gap photoluminescence at room temperature in GeSn layers grown on Si represents a significant breakthrough in the evolution of group IV materials. As shown in FIG. 10 the luminescence peak shifts to longer wavelengths as the Sn concentration is increased, and its peak value is very close to the direct gap energy obtained from ellipsometric studies of the dielectric function. While these low-Sn concentration alloys are expected to be indirect gap semiconductors, the separation between the direct and indirect edges is less than in pure Ge, and therefore the γ-valley minimum in the conduction band of the GeSn alloy is easily populated by a combination of photo- and thermal excitation. The indirect gap emission is far more sensitive to defects than the direct gap emission, and therefore it is not observed in these samples. This is similar to previous results for Ge layers on Si that have led to the recent announcement of lasing in these materials. The advantage of GeSn alloys is that their emission energy is tunable. Moreover, the separation between conduction band minima is also tunable, and this reduces (or eliminates altogether) the level of n-type doping needed to achieve lasing devices.

### Example 3

### Dilute Ge₁₋ₓSnₓ Film Growth

Depositions of the Sn-doped systems were conducted via SnD₄-assisted reactions of pure digermane directly on Si(100) at a low-temperature of T=390° C. and an pressure P=0.300 Torr. The Sn concentration in the films was varied in the 10¹⁹-10²⁰ cm⁻³ range by increasing the amount of SnD₄ in the reaction mixture while keeping the growth temperature constant. Under these conditions the growth rate was found to increase significantly in proportion to the amount of SnD₄, reaching a maximum value of about 20 nm/min, facilitating the growth of films with thicknesses exceeding 2.5 μm.

Below the concentration of 10¹⁹ cm⁻³ Sn, the growth rate diminished to a nearly impractical level, while well above the 10²⁰ cm⁻³ level the material produced is more characteristic of the Ge_{1-y}Sn_{y} alloys. Using the processing window of temperature, pressure, and Sn concentration identified herein, thick layers with flat surfaces and minimal dislocations densities can be produced, thereby circumventing the Stranski-Krastanov mechanism that characterizes the growth of Ge on Si. It is apparent that the presence of SnD₄ promotes a layer-by-layer crystal assembly while maintaining unprecedented high growth rates at the low temperatures employed. Conversely, as stated above, the use of pure digermane under the same low pressure and temperature hot wall CVD conditions does not produce any measurable film growth.

### Example 4

### Dilute Ge₁₋ₓSnₓ Characterization

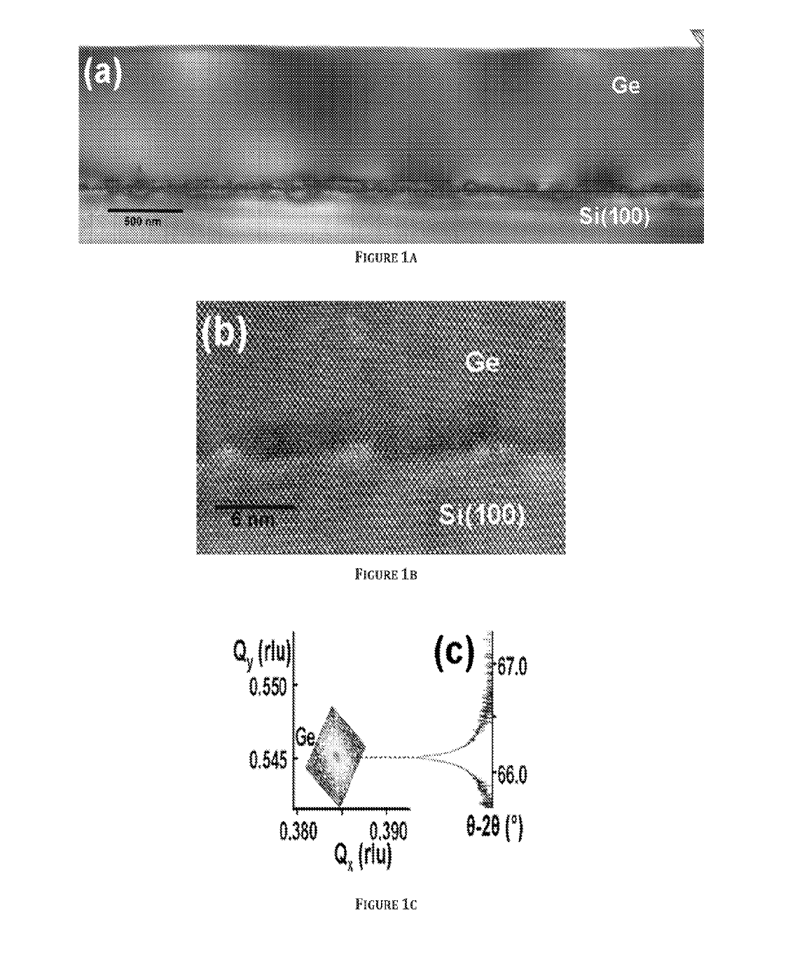

Extensive characterizations of the as-grown layers were performed using Rutherford Backscattering (RBS), Atomic Force Microscopy (AFM), Nomarski microscopy, Cross-sectional Transmission Electron Microscopy (XTEM) and X-Ray Diffraction (XRD). The RBS signal under channeling alignment (χₘᵢₙ) for the films shows extremely low values, and the AFM/Nomarski images reveal smooth surfaces entirely devoid of defects and imperfections. XTEM phase-contrast micrographs confirm the flat surface morphology and indicate that the bulk material is relatively free of threading defects (see FIG. 1a). High resolution imaging experiments detect the presence of periodic edge type dislocations confined to the interface plane (FIG. 1b), accommodating the significant lattice mismatch between the substrate and the films. The strain state of the film is determined by high resolution XRD measurements of the (224) reciprocal space maps and (004) peaks. Rocking scans of the (004) peaks reveal a FWHM of 800-900 arcsec, which is significantly reduced by Rapid Thermal Annealing (RTA) processing of the samples using a sequence of three 10 second cycles of heating at 680° C. The procedure markedly sharpens the XRD peak, leading to a reduction of the FWHM down to 145 arcsec. After annealing the film surface remains flat (RMS about 1 nm) and the layer RBS channeling is dramatically improved with final χₘᵢₙ, values in the range of 5-10%, which are close to the experimental limit for bulk Si wafers.

Since the Sn content in these samples is near the RBS detection limit, SIMS elemental analysis of the annealed layers were conducted which revealed a highly homogeneous profile of the element throughout the crystal at concentrations of around 10¹⁹ atoms/cm³. The SIMS data were calibrated using reference films containing 0 Sn (pure Ge) and 1.5% Sn as measured by RBS. Under the growth conditions employed here the Sn does not function as a surfactant but is incorporated as a fully substitutional atom in the average diamond lattice of the Ge-like material, as expected.

It has been shown that there is an inverse relationship between the growth temperature and the level of Sn incorporation into the Ge lattice via this CVD approach. For example alloys containing 0.6-3.0 Sn % are produced at 380-350° C. The doping levels produced here follow this latter trend and produce a true random solid solution with intrinsic structural properties and thermal stability close to those of the parent Ge material.

### Example 5

### Dilute Ge₁₋ₓSnₓ Electrical Properties

Electrical measurements were conducted on a series of films with thicknesses about 0.5-1 μm with a particular focus on samples with compositions in the 0.06-0.10% Sn range to compare their behavior to that of pure Ge. The Hall mobility, resistivity and carrier

TABLE 1
Summary of Hall measurement data (carrier concentration, n; mobility,
μ; resistivity, ρ) for a range samples containing 0.0-0.1% Sn,
obtained at room temperature using two contact methods.

| Thick- | | | μ | | | |
|---|---|---|---|---|---|---|
| ness | | | (cm²/ | ρ | | |
| (nm) | % Sn | N (cm⁻³) | V · s) | (Ω · cm) | | Contact |
| 500 | 0.00 | 3.60 × 10¹⁶ | 8.30 × 10² | | | |
| 800 | 0.06 | 2.60 × 10¹⁶ | 3.88 × 10² | 0.70 | {close oversize brace} | Indium |
| 1100 | 0.10 | 2.70 × 10¹⁶ | 2.74 × 10² | 0.95 | | |
| 500 | 0.00 | 4.10 × 10¹⁶ | 7.21 × 10² | 0.24 | | Cr |
| 800 | 0.06 | 2.85 × 10¹⁶ | 3.45 × 10² | 0.72 | {close oversize brace} | (20 nm)/ |
| 1100 | 0.10 | 1.76 × 10¹⁶ | 3.57 × 10² | 1.12 | | Au(200 nm) |

concentrations for representative films and a reference pure Ge counterpart (grown via the gas-source MBE method, see Wistey et al., Appl. Phys. Lett. 90 (8), 082108 (2007)) are listed on Table 1. Mindful that ohmic contacts are difficult to produce on Ge-like materials, two types of metal contacts were used to establish the reproducibility of the measurements. As seen in Table 1, similar values were obtained for the two types of contacts. The samples were found to be p-type with carrier concentrations in the 10¹⁶ cm⁻³ range. The measured hole mobility for the pure Ge films-μₕ=700-800 cm²V⁻¹s⁻¹ is about one-half the mobility μₕ=1500 cm²V⁻¹s⁻¹ obtained in bulk Ge samples with similar hole concentrations (see, Golikova et al., Fizika Tverdogo Tela 3 (10), 3105 (1961)). The reduced mobility may be due to carrier scattering at the Si—Ge interface. An additional factor of about 2 reduction in mobility was found when comparing the Sn-doped samples with pure Ge. At carrier concentrations in the 10¹⁶ cm⁻³, the room temperature mobility of bulk Ge is limited by acoustic phonon and ionized impurity scattering (see, Golikova et al., Fizika Tverdogo Tela 3 (10), 3105 (1961); and Kearney and Horrell, Semicond. Sci. Technol. 13 (2), 174 (1998)). Neither mechanism can lead to a halving of the mobility for Sn concentrations as small as 0.06%. In the case of ionized impurity scattering, the only effect of alloying might be a change in screening, but such effect should be negligible for small Sn concentrations. Similarly, acoustic phonons depend on the material's density and elastic constants, which will change trivially at low Sn concentrations. The only mechanism that might account for the observed decrease in mobility is alloy scattering. In the case of Ge₁₋ₓSiₓ alloys, their hole mobility is halved, relative to pure Ge, for x=0.05 (see, Fischetti and Laux, J. Appl. Phys. 80 (4), 2234 (1996)). Assuming that the mobility limited by alloy scattering is of the form (see, Kearney and Horrell, Semicond. Sci. Technol. 13 (2), 174 (1998)):

$${μ}_{alloy} = \frac{A {e}^{2}}{x ( 1 - x ) {U}_{AL}^{2}} , \qquad ( 1 )$$

where A is a constant and U_{AL} the so-called alloy potential, A=77 cm²V s⁻¹ was obtained using U_{AL}=0.9 eV (see. Fischetti and Laux, J. Appl. Phys. 80 (4), 2234 (1996)) and applying Mathiessen's rule to fit the mobility of Ge_{0.95}Si_{0.05}. If Eq. (1) is assumed valid for Ge_{1-y}Sn_{y} alloys with the same value of A, a similar fit of the experimental mobilities in Table 1 requires U_{AL}=12 eV, about one order of magnitude larger than in Ge₁₋ₓSiₓ alloys. Such an increase is not unreasonable considering the fact that the alloy potential is also responsible for the observed bowing in the compositional dependence of the optical transition energies. In the case of the lowest direct gap E₀, which involves the hole states that contribute to the mobility, the bowing parameter is indeed one order of magnitude larger in Ge_{1-y}Sn_{y} alloys relative to Ge₁₋ₓSiₓ alloys (see, D'Costa et al., Phys. Rev. B 73 (12), 125207 (2006)). These crude estimates confirm that alloy scattering is a plausible explanation for the observed decrease in mobility in the Sn-doped samples. The reason for the enhanced alloy potential in Ge_{1-y}Sn_{y} alloys is the much larger size and Phillips electronegativity mismatch between Ge and Sn as compared to the mismatch between Si and Ge(see, D'Costa et al., supra).

### Example 6

### Device Studies

A pin photodiode (FIG. 2a) was fabricated on a highly doped n-type Si(100) wafer (bottom electrode) with a resistivity ρ=0.003 Ωcm. The diode consists of an about 450 nm thick nominally intrinsic Ge_{0.9975}Sn_{0.0025} (about 1.1×10²⁹ cm⁻³ Sn) film followed by a 150 nm p-type Ge_{0.9997}Sn_{0.0003} capping layer (about 1.0×10¹⁹ cm⁻³ Sn). The purpose of the lower Sn content in the top layer was to minimize the 1550 nm absorption above the intrinsic region of the diode. The layers were grown using digermane and stannane. For the p-type layer, appropriate amounts of diborane were included into the reaction mixture. The RBS analysis indicates a nominal thickness of 590 nm for the entire film, and an average Sn content near the detection limit. The channeled spectrum shows a high degree of epitaxial alignment and excellent crystalline quality, as expected. SIMS elemental profiles indicate a uniform distribution of the Sn substituents and the B dopants, as shown in FIG. 2b. Note that both the Sn and B profiles show a steep and abrupt step at the interface between the p-doped and intrinsic region, indicating minimal interdiffusion. A calibration of the mass yield gives the Sn concentrations quoted above. Both the on-axis XRD plots and the (224) reciprocal space maps reveal a single peak corresponding to a tetragonally distorted diamond-structure lattice with dimensions a=5.6658 Å and c=5.6553 Å. Using elastic constants for Ge, a relaxed lattice parameter a₀=5.6598 Å was obtained. Using for relaxed Ge_{1-y}Sn_{y} alloys the lattice parameter (in Å) a₀(y)=5.6575(1−y)+6.4894y+0.063y(1−y), where the bowing parameter was obtained from Chizmeshya's et al. ab initio calculations. (see, Chemistry of Materials 15 (13), 2511 (2003)). y=0.26% was obtained from the x-ray data, in very good agreement with the SIMS calibration for the intrinsic layer. The inability to resolve the two layers is probably due to their close similarity and the much larger thickness of the intrinsic layer.

The samples were processed using similar protocols to those employed to fabricate pure Ge and Ge_{0.98}Sn_{0.02} photodiodes, as described previously (see, Roucka et al., IEEE J. Quant. Electron. 47 (2), 213 (2011)). In this case circular mesas with diameters ranging from 50 μm to 3 mm were defined by photolithography and etched using by reactive ion plasmas generated by BCl₃. The mesas were passivated by a 270 nm thick SiO₂ layer, which also serves as antireflection coating. The Cr/Au metal contacts were deposited by e-beam and defined by lithography.

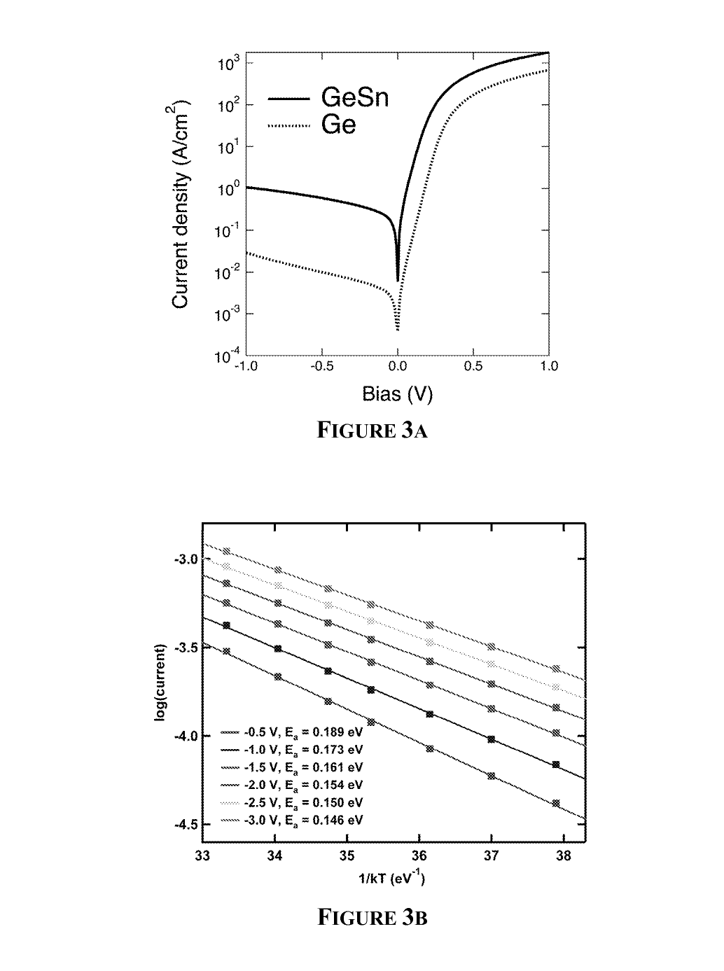

Current-density vs. voltage measurements were conducted and a representative curve for a typical 100 μm device is shown in FIG. 3a, where it is compared with data measured from a similar pure-Ge on Si device consisting of a 390 nm intrinsic layer, a 100 nm p-type top layer, and a 420 nm SiO₂ cap layer. The curves exhibit a similar rectifying behavior, but with a somewhat better ideality factor (1.2) in the Ge device than in Ge_{0.9975}Sn_{0.0025} device (1.3). The dark current densities at −1V are about one order of magnitude higher in the Ge_{0.9975}Sn_{0.0025} device. On the other hand, similar diodes based on Ge_{0.98}Sn_{0.02} layers show dark currents close to 10 A cm⁻², so that the Sn-doped material represents a significant improvement over bona fide alloys. In the case of the pure Ge device, the dark current has a thermal activation energy Eₐ=0.32 eV at V=−1V, which is close to to E_{g}/2, where E_{g} is the fundamental band gap (see, Roucka et al., IEEE J. Quant. Electron. 47 (2), 213 (2011)). This clearly indicates a Shockley-Read-Hall (SRH) generation mechanism. In the Sn-doped material, substitutional Sn has a measurable impact on carrier mobilities via alloy scattering, but it can be ruled out as the source of additional SRH trap states due to the isoelectronic nature of Sn and Ge. In fact, a study of the temperature dependence of the dark current (FIG. 3b) reveals an activation energy of Eₐ=0.17 eV at −1V, which is substantially below the value of Eₐ obtained in the pure Ge diode. This indicates that the excess dark current in the Sn-doped device is not due to enhanced SRH generation but to some alternative mechanism.

Very low values of the activation energy have been associated with tunneling transitions (see, Huang et al., IEEE J. Quant. Electron. 43 (3), 238 (2007); and Loke et al., J. Appl. Phys. 102 (5), 054501 (2007)). At this point it is unclear if the defects that cause the excess dark current in the Sn-doped diodes are located at the interface with the Si substrate or in the material's bulk. The microstructural similarities between the pure-Ge-on-Si and Sn-doped Ge-on-Si interfaces, combined with the observation of a standard SRH mechanism in the pure-Ge-on-Si diodes, suggest a bulk origin for the excess dark current in the Sn-doped devices. However, the detailed mechanism by which layer-by-layer growth proceeds at the interface with Si may be very different in the two cases, since the pure-Ge material is grown by gas-source molecular beam epitaxy of Ge₂H₆ assisted by the CH₂(GeH₃)₂ metalorganic additive(see, Wistey et al., Appl. Phys. Lett. 90 (8), 082108 (2007)), whereas the Sn-doped material is grown via CVD of Ge₂H₆ in the presence of SnD₄. Thus one cannot rule out the possibility that different type of interface states may be generated by each of these growth processes.

It is interesting to note that in diodes based on Ge_{0.98}Sn_{0.02} layers the measured dark count activation energy at −1V is even smaller (Eₐ=0.09 eV, see, Roucka et al., IEEE J. Quant. Electron. 47 (2), 213 (2011)). Thus the intermediate Eₐ value obtained for the Ge_{0.9975}Sn_{0.0025} device may signal the onset of a transition from tunneling to SRH generation. A final point to make regarding the I-V characteristics is that our investigations of the dependence of the dark current density on the device diameter suggests that the leakage currents do not originate from the sidewalls of the mesas.

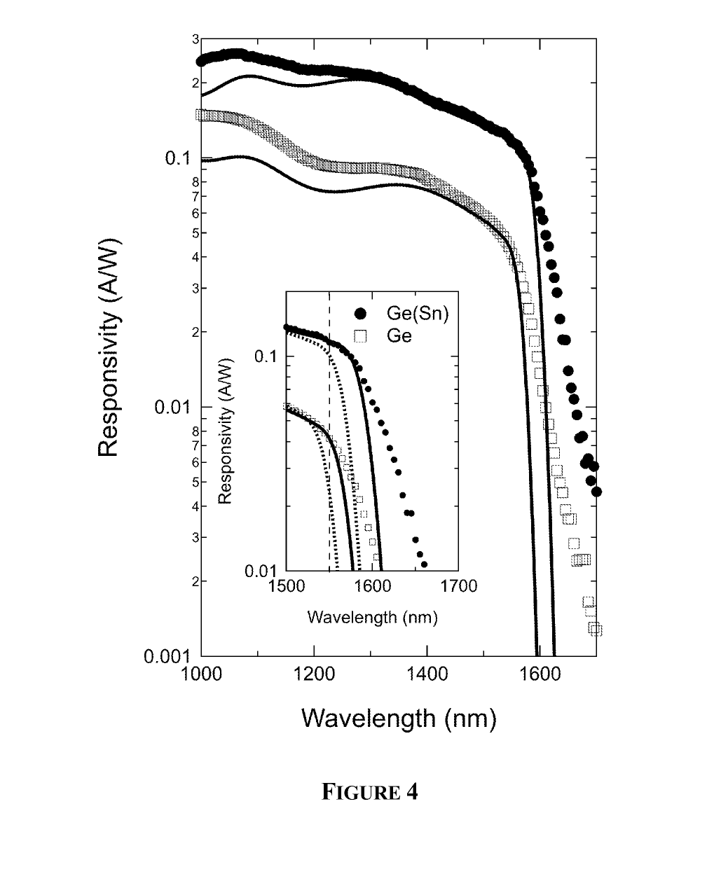

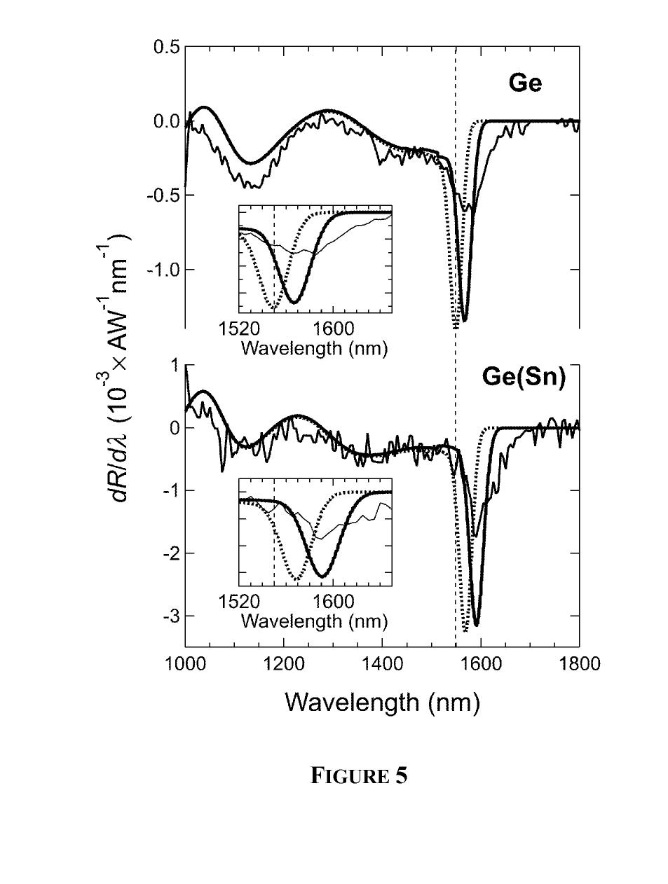

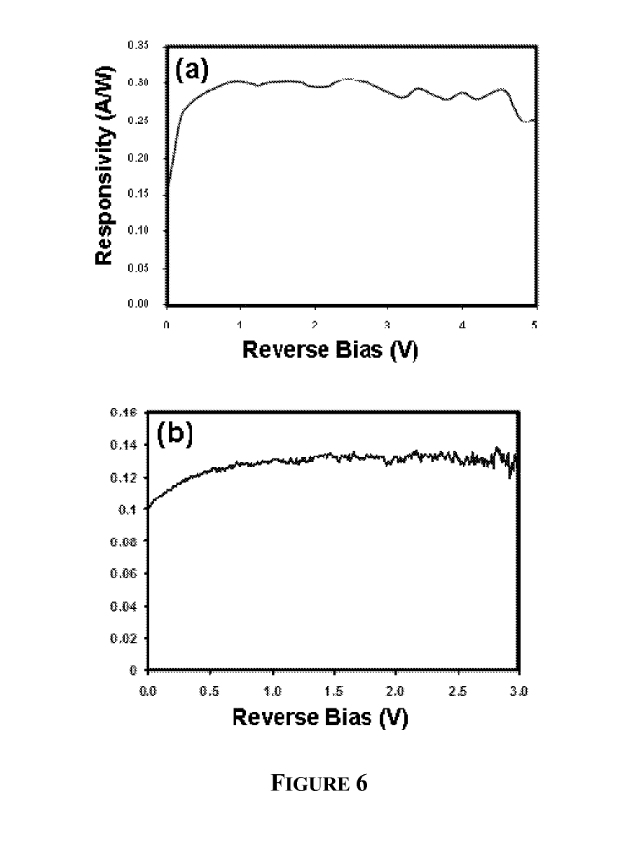

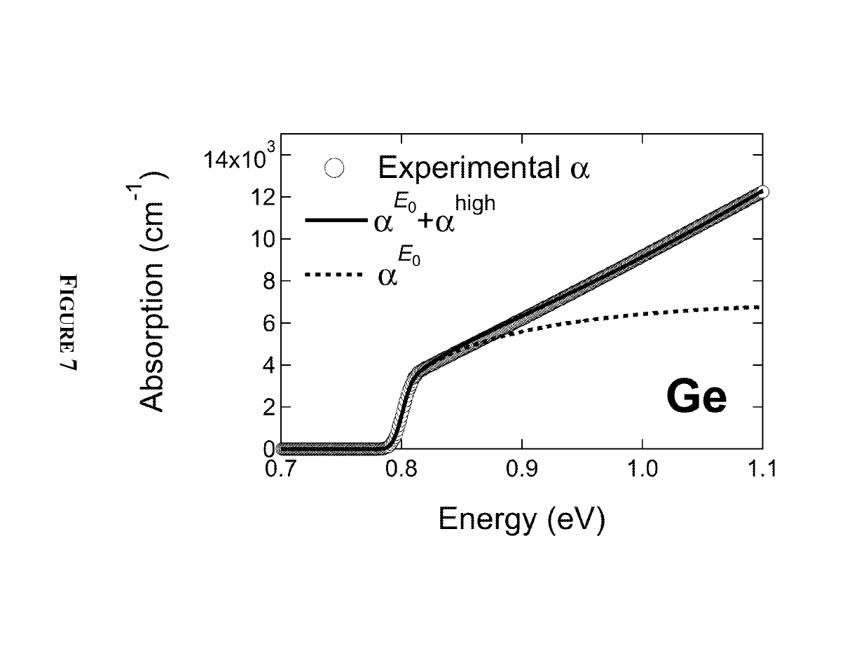

The spectral responsivity at zero bias for the two diodes in FIG. 3a is shown in FIG. 4. The measurements were performed by focusing the monochromatized light from a halogen lamp onto the surface of the devices using optical fibers. The light was modulated with a mechanical chopper. The diode photocurrent induced a voltage on a 10 kΩ load resistor that was measured with a lock-in amplifier. The incident power was obtained by measuring the light passing through an aperture with a diameter identical to that of the device. The absolute responsivities are not directly comparable because the layer thicknesses are not identical, but the optical properties of the component materials manifest themselves in the different spectral dependences of the responsivity. The large drop in responsivity beyond about 1600 nm is associated with the lowest direct band gap of these materials near 0.8 eV. Superimposed with the step-like onset of responsivity at 1600 nm oscillations were observed at shorter wavelengths that are due to interference effects. These are enhanced by computing the derivatives; dR/dλ, of the responsivities, as shown in FIG. 5.

The most striking feature in FIGS. 4 and 5 is the clear shift to longer wavelengths in the responsivity onset corresponding to the Sn-doped device, indicating a direct band gap reduction that is clearly measurable even for a Sn concentration as low as 0.25%. We also note that this shift is not accompanied by a broadening of the absorption edge, as seen in the case of Ge_{0.98}Sn_{0.02} alloys (see, Roucka et al., IEEE J. Quant. Electron. 47 (2), 213 (2011)). If anything, the direct gap onset appears to be slightly sharper in the Sn-doped device. Since the observed shift between the two diodes is comparable in magnitude to those typically induced by strain, a detailed model is needed to quantify the relative contributions from composition and strain. The model must also account for interference effects caused by the optical mismatch of the different layers. In Roucka (supra), the device responsivity was modeled as

$$R = ( \frac{e λ}{hc} ) [ f {η}_{c} ( 1 - {T}_{+} - {R}_{+} ) + exp ( {α}_{top} {d}_{top} ) f {η}_{c} {T}_{+} {R}_{back} ( 1 - {T}_{-} - {R}_{-} ) ] \qquad ( 2 )$$

Here e is the electron charge, λ the wavelength, h Planck's constant, c the speed of light, η_{c} the collection efficiency, T₊ (R₊) the transmittance (reflectance) of the entire oxide/diode stack on Si under illumination from the top surface, R_{back} the reflectance at the back surface of the Si wafer, and T₋ (R₋) the transmittance (reflectance) of the oxide/diode stack for illumination by the light reflected from the back surface, αₜₒₚ the absorption coefficient of the top p-type layer, and dₜₒₚ its thickness. The factor

$$f = \frac{1 - exp ( - {α}_{int} {d}_{int} )}{exp ( {α}_{top} {d}_{top} ) - exp ( - {α}_{int} {d}_{int} )} , \qquad ( 3 )$$

where αᵢₙₜ is the absorption coefficient and dᵢₙₜ the thickness of the intrinsic layer, gives the fraction of the incoming light absorbed in the intrinsic layer of the structure, which is assumed to provide the only contribution to the photocurrent. The corresponding fraction for the light reflected at the back surface is ƒ exp(αₜₒₚdₜₒₚ). Eq. (3) treats the light traveling through the device structure as fully coherent, but neglects the coherency between the light traveling toward the back surface of the Si wafer and the light reflected at this surface. This should be an excellent approximation given the macroscopic thickness of the Si wafer.

The transmittances and reflectances needed for Eq. (2) are calculated using standard transfer-matrix techniques. In Roucka (supra), for this purpose, tabulated optical constants for SiO₂, Ge, Ge_{0.98}Sn_{0.02} and Si were used, but this approach is clearly impractical for exploring the effect of strain and composition. The alternative is to use for the active layers of our devices the analytical model introduced in D'Costa (see, Semicond. Sci. Technol. 24 (11), 115006 (2009)). The model provides a remarkably accurate account of the direct gap absorption in pure Ge based on elementary k·p theory, and therefore it can be used for Ge_{1-y}Sn_{y} alloys by inserting the experimental compositional dependence of the relevant optical transitions. Moreover, since the model accounts for the absolute value of the absorption without any adjustable parameter, it can be used to predict not only shifts in the absorption edge but also the compositional dependence of the absorption strength, which is particularly important for modeling responsivities. Strain effects can also be easily included via deformation potential theory. A disadvantage of the model, however, is that it is limited to the spectral region immediately around the material's direct gap. Since the experimental responsivity in FIG. 4 covers a wider range down to 1000 nm, a corrective term was added to fit the experimental absorption up to this wavelength. The resulting hybrid approach, in which the E₀ absorption is computed from “first principles” while the above-E₀ absorption is empirically fit to the experimental data, provides a convenient tool for studying subtle changes around E₀ while yielding quantitative responsivity estimates over a much wider range. The details of this hybrid absorption model are provided in the Example 5.

The calculated responsivities for the two devices are shown in FIG. 4 and their derivatives appear in FIG. 5. For these calculations, the measured strains of 0.14% in the intrinsic layer of the Sn-doped device and 0.088% in the pure-Ge device were used. The band gap of the Ge_{1-y}Sn_{y} alloy was interpolated between that of Ge and α-Sn using the standard expression E₀(y)=E₀^{Ge}(1−y)+E₀^{Ge}−by(1−y) with E₀^{Ge}=0.803 eV, E₀^{Sn}=−0.4 eV, and b=−2.5 eV (Ref. 31). The overall thickness of the intrisinc and p-doped layer was adjusted to match the oscillations in FIG. 5, and the result was within 5% of the value determined from the RBS measurements. The collection efficiency was adjusted to reproduce the experimental responsivity at 1550 nm, and η_{c}=0.67 was obtained for the Sn-doped diode and η_{c}=0.38 for the pure-Ge diode. These less than perfect collection efficiencies at zero bias are probably related to the 10¹⁶ cm⁻³ residual doping in the intrinsic layers. It is apparent from FIG. 4 that the collection efficiencies are higher at short wavelengths.

At long wavelengths, the drop in the theoretical responsivity curve is much sharper than observed experimentally, an effect that can also be seen in the derivative profiles. This is because our simulation does not include indirect gap absorption. In spite of this limitation, the model accounts very well for the relative spectral shift between the two diodes. To understand the contributions to this shift, the inset to FIGS. 4 and 5 (as dotted lines) shows the expected responsivities and their derivatives in the absence of any strain. The effect of strain and composition are seen to be of the same order of magnitude.

The derivative curves in FIG. 5 offer an easy graphical interpretation of the “diminishing returns” condition mentioned in the introduction. The negative peak near 1550 nm represents the spectral range over which the responsivity changes rapidly as a function of strain and/or composition. Once this peak is to the right (longer wavelengths) of the vertical line corresponding to 1550 nm, further increases in Sn concentration and/or tensile strain lead to much smaller gains in responsivity. It is apparent that the Sn-doped sample has a nearly ideal combination of tensile strain and composition to meet this condition. To accomplish the same result based solely on pure Ge, a tensile strain level of 0.2% would be needed. In fact, such a detector was fabricated by Liu et al. (Appl. Phys. Lett. 87 (10), 103501 (2005)). They report a responsivity R=0.56 A/W at 1550 nm from a 2410 nm-thick Ge on Si diode in which a tensile-strain level of 0.2% is obtained by growing the bulk of the Ge layer at 700° C. and annealing the sample at 900° C. At 1550 nm and assuming η_{c}=1, this model predicts a responsivity R=0.55 A/W for this diode—in very good agreement with the experimental value—and R=0.54 A/W from a detector based on a material with the same Sn concentration and strain level as in dilute Sn-doped Ge. On the other hand, to obtain the same responsivity using perfectly relaxed Sn-doped layers, a Sn concentration of 0.6% is needed. This is less than the concentration of 0.8% that would be needed to match the lowest direct band gap in both materials, following the analysis in the introduction. The discrepancy can be understood by recalling that strain broadens the absorption edge due to the light-heavy hole splitting. While this broadening is very small in the derivative profiles shown in FIG. 5, a similar plot for a tensile strain level of 0.2% shows clear evidence of the separate absorption edges associated with the light- and heavy-hole bands.

For η_{c}=1, the model predicts R=0.30 A/W at 1300 nm and R=0.17 A/W at 1550 nm for the Sn-doped sample. In FIG. 3, the bias dependence of the responsivity at these two wavelengths is shown; at 1300 nm complete carrier collection is approached at reverse biases above 0.5 V. At 1550 nm, on the other hand, the asymptotic value of the responsivity is 0.13 A/W, which corresponds to a collection efficiency of η_{c}=0.74. These bias-dependence measurements were carried out under laser illumination, and therefore the zero bias values are probably not directly comparable to those obtained under much weaker lamp illumination.

In conclusion, the doping-level amounts of Sn are sufficient to engineer the optical properties of Ge around the critical 1550 nm wavelength. The manipulation of the absorption edge via Sn doping makes it possible to decouple the conditions that produce the highest-quality growth (which normally determine the final strain level in the material) from the desired value of the aborption edge, which is controlled by both strain and composition. Using the Sn concentration as an adjustable parameter, large increases in responsivity can be achieved while keeping the growth temperature at very low values compatible with CMOS processing. The same increases in responsivity using pure Ge layers require high levels of tensile strain that can only be achieved at much higher processing temperatures. Compared with previously published results using Ge_{0.98}Sn_{0.02} alloys, the much lower Sn concentrations in the Sn-doped samples virtually eliminate alloy broadening of the optical transitions, and lead to dark current densities that are one order of magnitude lower. The results suggest that Sn-doped Ge has an intriguing potential in the field of silicon photonics.

### Example 7

### Hybrid Absorption Model

We express the absorption in Ge-like materials as

α(E)=α^{E}^{₀}(E)+α^{high}(E) (4)

The first term accounts for the absorption related to the lowest direct band gap E₀, and the second term incorporates above-band gap transitions. Indirect transitions below the direct gap are not included. The E₀ transitions involve the heavy- and light-hole valence bands and the s-like conduction band near the k=0 (Γ) point in the Brillouin zone. The dispersion of all these bands is assumed to be parabolic. We express the E₀ absorption as

α(E)=α₀^{chh}(E)[ƒₕₕ(E)−ƒ_{c}(E)]+α₀^{clh}(E)[ƒₗₕ(E)−ƒ_{c}(E)] (5)

Here the superscripts chh (clh) refer to transitions between the heavy hole band hh (light hole band lh) and the conduction band c. The quantity α₀^{cv}(E) with v=hh or lh is the absorption coefficient for an empty conduction band and a full valence band. The Fermi functions ƒᵥ(E) and ƒ_{c}(E) give the occupation probability for the valence and conduction band states separated by an energy E. We express the absorption in terms of the real (∈₁) and imaginary (∈₂) parts of the empty-band dielectric function as α₀^{cv}(E)=E∈₂^{cv}(E)/[hc\sqrt{∈₁(E)}], where c is the speed of light and h=h/(2π). Since the value of ∈₁ changes very little at the E₀ gap, we simply use for the real part an expression of the form ∈₁(E)=11.03−11.88/(E−2.62), with E in eV, which has been fit to the experimental real part of the dielectric function in pure Ge. The compositional and strain dependence of ∈₁ are neglected. For each of the v=hh heavy- and v=lh light-hole components, the imaginary part of the dielectric function is written as

∈₂^{cv}(E)=∈ₓ^{cv}(E)+∈_{ƒ}^{cv}(E)S^{cv}(E) (6)

where ∈ₓ^{cv} the below-band gap excitonic contribution given by³²

$${ɛ}_{2}^{cv} ( E ) = \frac{16 π {\vert P \vert}^{2} {e}^{4} {μ}_{cv}^{2} {R}_{cv}}{{E}^{2} {h}^{2} {m}^{2} {ɛ}_{0}} {\sum }_{n = 1}^{∞} \frac{1}{{n}^{3}} ( E - {E}_{n} ) , \qquad ( 7 )$$

where P is the momentum matrix element, e and m the free electron charge and mass, μ_{cv} the reduced electron-hole mass, ∈₀ the static dielectric constant, and the Rydberg is defined as R_{cv}=μ_{cv}e⁴/(2h²∈₀²). With this definition the excitonic energy levels can be written as Eₙ=E₀ᵥ−R_{cv}/n², where E₀ᵥ is the light-hole (heavy-hole) direct band gap for v=lh (v=hh). The second term in Eq. (6) is given by the dielectric function ∈_{ƒ}^{cv} for free, uncorrelated electron-hole pairs multiplied by the Sommerfeld enhancement factor S^{cv}. These quantities are given by Yu and Cardona, Fundamentals of Semiconductors: Physics and Materials Properties. (Springer-Verlag, Berlin, 1996):

$$\begin{matrix}{ɛ}_{f} ( E ) = \frac{4 \sqrt{2} {e}^{2} {P}^{2} {μ}_{cv}^{3 / 2}}{3 {m}^{2} h {E}^{2}} {( E - {E}_{0 v} )}^{1 / 2} Θ ( E - {E}_{0 v} ) \\ and & ( 8 ) \\ {S}^{cv} ( E ) = \frac{{τ}_{cv} {e}^{{τ}_{cv}}}{sinh {τ}_{cv}} ; {τ}_{cv} = π {\vert \frac{{R}_{cv}}{E - {E}_{0 v}} \vert}^{1 / 2} , & ( 9 )\end{matrix}$$

Here Θ(x) is the unit step function.
The needed E₀ᵥ=E₀ₗₕ light-hole direct gap and E₀ᵥ=E₀ₕₕ heavy-hole direct band gap are calculated as function of the strain using standard deformation potential theory. The corresponding expressions are:

$${E}_{0 lh} = {E}_{0} + \frac{{Δ}_{0}}{2} + δ {E}_{0} - \frac{1}{4} δ {E}_{001} - \frac{1}{2} \sqrt{\frac{9}{4} {( δ {E}_{001} )}^{2} + {Δ}_{0}^{2} + {Δ}_{0} δ {E}_{001}} \\ {E}_{0 hh} = {E}_{0} + δ {E}_{0} + \frac{1}{2} δ {E}_{001} \qquad ( 10 )$$

Here Δ₀ is the spin-orbit splitting at the Γ-point of the Brillouin zone and

δE₀=2aₕ(1−C₁₂/C₁₁)∈ₚ

δE₀₀₁=−2b(2C₁₂/C₁₁−1)∈ₚ′ (11)

where ∈ₚ=(a−a₀)/a₀, C₁₁ and C₁₂ are elastic constants, aₕ the hydrostatic E₀ gap deformation potential, and b the shear deformation potential.

For pure Ge, all parameters needed for the evaluation of Eqs. (6)-(11) are independently measured (including the matrix element P, which obtains from the experimental effective masses using k·p theory), and the values we use are summarized in Table Al. For Ge_{1-y}Sn_{y} alloys the band structure parameters are interpolated in the spirit of k·p theory as discussed in D'Costa (Semicond. Sci. Technol. 24 (11), 115006 (2009)). The deformation potentials and elastic constant ratio C₁₂/C₁₁ are linearly interpolated with those of α-Sn. Of course, given the doping-level amounts of Sn in this work, the interpolated values are virtually identical to those of pure Ge. The only compositional dependence that plays a critical role in our simulations is that of the direct gap E⁰, which, as indicated above, is taken as E₀(y)=E₀^{Ge}(1−y)+E₀^{Ge}−by(1−y) with E₀^{Ge}=0.803 eV, 4, E₀^{Sn}=−0.4 eV, and b=−2.5 eV (see, Mathews et al., Appl. Phys. Lett. 97 (22), 221912 (2010).

The occupation probability functions ƒ_{c′} ƒₗₕ and ƒₕₕ depend on the Fermi level E_{F}. The effect of doping on the absorption coefficient is partially included by computing the value of E_{F} corresponding to the layer's doping concentration. In the case of the nominally intrinsic layer, ƒ_{c′}=0 and ƒₗₕ=ƒₕₕ=1 is an excellent approximation. For p>10¹⁹ cm⁻³ the effect of doping on the absorption is not negligible, but it has a small effect on our computed responsivities because the top p-layer is thin and is not assumed to contribute to the photocurrent.

In FIG. 7 we show the experimental absorption in pure Ge and, as a dashed line, the results from Eq. (5) convolved with a Gaussian with a FWHM of 15 meV. If we attribute this broadening to lifetime effects, a convolution with a Lorentzian appears to be physically more meaningful, and this is what we used in Ref. 9. However, the Gaussian function gives a nearly perfect agreement with the experimental absorption, and therefore we use this approach for our responsivity simulations.

TABLE A1
Band structure and elastic parameters for pure Ge used to compute
the optical absorption. A discussion on the selection of these
parameters is given in D'Costa et al. Semicond. Sci. Technol.
24 (11), 115006 (2009); and D'Costa et al., Thin Solid Films
518 (9), 2531 (2010)

| E₀ | P²/m | | | | | aₕ | b | |
|---|---|---|---|---|---|---|---|---|
| (eV) | (eV) | μ_{clh}/m | μ_{cnh}/m | ε₀ | Δ₀ (eV) | (eV) | (eV) | C₁₂/C₁₁ |
| 0.803 | 12.61 | 0.0183 | 0.0300 | 16.2 | 0.297 | −9.64 | −1.88 | 0.3755 |

As indicated in D'Costa (Semicond. Sci. Technol. 24 (11), 115006 (2009)), it is critical to include excitonic effects if good agreement with experiment is desired. It is important to point out that in our calculation this is done by computing the excitonic enhancement separately for the hh→c and lh→c transitions. This is clearly not exact, but the details of the excitonic interaction may not matter in our case because our room temperature broadening is much larger than the exciton binding energy.

Above the band gap, our calculated absorption falls below the measured one because the electronic bands are not parabolic over a large wave vector range and because additional bands contribute to the absorption. We find that for E<1.3 eV, the difference between the experimental and the E₀ absorption is very well described by an empirical expression of the form

$${α}^{high} ( E ) = A \{ 1 - {exp [ - \frac{ln ( E / {E}_{0} )}{B} ]}^{2} \} , \qquad ( 12 )$$

with A=1.088×10⁵ cm⁻¹ and B=1.377. Since this expression vanishes for E=E₀, the contribution of this term to the critical near band gap region is negligible. However, it is important to take it into account to be able to model the responsivity over the entire spectral range covered in FIG. 4. In FIG. 7 we show as a solid line the absorption using Eq. (4) and we see that the agreement with experiment is very good.

### Example 8

The formation of undoped Ge(Sn) films was conducted directly on high resistivity Si(100) wafers via reactions of digermane (Ge₂H₆) and deuterated stannane (SnD₄) diluted by large amounts of high-purity H₂. The deposition experiments were performed at low temperatures of 390-400° C. and 0.300 Torr pressure using ultra high vacuum chemical vapor deposition (UHV CVD) methods and protocols similar to those described above. The Sn concentration was also varied over a much more limited range of 10¹⁹ atoms per cm⁻³ (0.05%-0.15% Sn)—but controllably and reproducibly—by adjusting the amount of SnD₄ in the reaction chamber. Films with thicknesses up to 2 μm were produced at an average growth rate of 20 nm/min. The growth rate did not increase monotonically as the SnD₄ content is further reduced in the digermane mixture (2%-3% by volume), but eventually began to decrease. In fact, the use of pure digermane did not produce any measurable film growth at the low temperatures and low pressures (0.3-0.4 Torr) employed. This processing window of temperature and SnD₄ flux is enables fabrication of thick and atomically flat surfaces that are devoid of surface defects and imperfections over large lateral areas of at least 100 μm, as required for device applications. The experiments suggest that a minimum concentration of SnD₄ at the growth front to ensures layer-by-layer crystal formation while maintaining unprecedented high growth rates at the low temperature employed.

The films were characterized by Rutherford backscattering (RBS), atomic forcemicroscopy (AFM), Nomarski optical microscopy, cross-sectional transmission electron microscopy (XTEM), and X-ray diffraction (XRD). The data collectively indicate that the layer morphology and crystallinity are improved, compared to those of pure Ge films grown via our previously developed low-pressure CVD approach. The latter typically utilizes low-temperature reactions of Ge₂H₆, which is the main source of Ge, and trace amounts of CH₂(GeH₃)₂ metal-organic additives to produce device-quality materials with optical/electrical response similar or better than the state of the art (see, Roucka et al., IEEE J. Quantum Electron. 2011, 47, 213-222).

Here, initial examination of the samples using Nomarski microscopy showed that the layer surface was uniform, smooth, and featureless. Complementary AFM scans indicate a root-mean-square (rms) roughness of <1 nm for large areas in the range of 20 μm×20 μm. XTEM micrographs confirm the flat surface morphology and indicate that the bulk material is devoid of threading defects within the typical field of view. High-resolution images reveal the presence of quasiperiodic edge-type dislocations localized at the interface of the heterojunctions. These defects are spaced ˜8 nm apart and serve to fully absorb the differential strain between the substrate and the films. RBS analysis corroborates the XTEM-observed film thickness and, in some cases, reveals a weak Sn signal appearing slightly above the spectrum background, indicating that the dopant level is near the RBS detection limit of ˜0.1%-0.15%, as shown in FIG. 11. Since the Sn content, in most samples, is below the RBS detection capability, we conducted routine SIMS analysis of all samples to determine the exact Sn content reliably and reproducibly. These SIMS data were calibrated using reference films containing 0% Sn (pure Ge) and 1.5% Sn, as measured by RBS. The SIMS study reveals a highly homogeneous Sn profile throughout the crystal at concentrations of ˜10¹⁹ atoms/cm³.

High-resolution XRD measurements of the (224) and (004) Bragg peaks show that all materials are essentially strain-free “as grown,” regardless of their thickness (0.5-3 μm). This was a surprising outcome, since residual strains are very difficult to avoid in defect-engineered heteroepitaxy of highly mismatched materials. In particular, they are extremely common in Ge or Ge_{1-y}Sn_{y} layers grown directly on Si(100) at 350-400° C., thereby limiting the overall thicknesses that can be achieved. We find that the vanishing strain in the present case may be due to an optimal interplay between the Sn incorporation and the growth temperature, leading to facile integration of several micrometers and beyond film thicknesses. We have previously shown that an appropriate amount of Sn prevents island formation. The relatively higher temperature range accessible due to the low Sn content relieves local strain fields in the growth front. These favorable conditions ensure complete relaxation of the growing crystal from the very onset of layer formation, yielding atomically flat films with unprecedented thicknesses up to 3 μm at high growth rates up to 30 nm/min.

The as-grown films exhibit relatively narrow (004) rocking curves with a typical full width at half-maximum (fwhm) of 800 arcsec, indicating a relatively low mosaic spread. This is significantly improved by rapid thermal annealing (RTA) processing at 680-725° C. for 10 s. The procedure markedly sharpens the XRD peak, leading to a reduction of the fwhm down to 200-150 arcsec. This value is lower than the best observed to date for the best Ge-on-Si samples. RBS ion channeling reveals a high degree of epitaxial alignment in the as-grown samples. This was significantly improved by subjecting the materials to RTA processing, as shown in FIG. 11, where final χmin values are <8%. Hall-effect measurements of the as-grown samples indicate that the material is p-type with background hole concentrations in the range of 2×10¹⁶ cm⁻³.

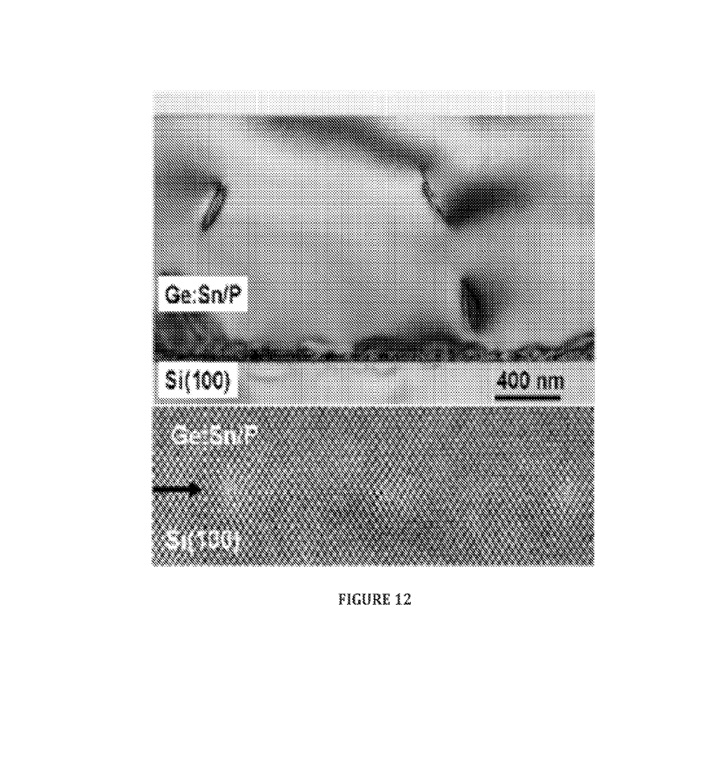

Intentional n-doping with P atoms was then conducted in situ using the single-source P(GeH₃)₃. This process yields tunable and highly controlled atomic profiles of the donor atoms. Carrier densities in the range of 1×10¹⁸ cm⁻³ to 2×10¹⁹ cm⁻³ were readily achieved by judiciously adjusting the P(GeH₃)₃/Ge₂H₆ ratio in the reaction mixture. The resultant layers exhibit flat surfaces, fully relaxed strain states, and crystallinity/morphology comparable to those observed in the intrinsic materials. However, the microstructure of heavily doped films near the 2×10¹⁹ cm⁻³ level also exhibits occasional isolated defects across the layer (see FIG. 12). These seem to abruptly annihilate or terminate without further propagation through the crystal, and are presumably caused by the high concentration of P atoms. Despite these imperfections, the PL performance of these materials was far superior to that of undoped counterparts. All n-type samples were subjected to RTA treatments at 725° C. for 10 s, producing a significant improvement in the crystal quality and optical response. Under these conditions the active carrier concentration remained remarkably unchanged, indicating that no measurable out-diffusion of P atoms had occurred.

### Example 9

The PL experiments described here were performed using a 980-nm laser focused to an about 100-μm spot. The average incident power was 200 mW. The emitted light was analyzed with an f=320 mm spectrometer equipped with a 600 lines/mm grating blazed at 2 μm, and detected with a single channel, liquid nitrogen (LN₂)-cooled extended InGaAs receiver (1.3-2.3 μm range). We find that the peak position, which is assigned to the direct gap (E₀), is identical for both samples, confirming that the extremely small amount of Sn in the Ge(Sn) material does not shift the emission wavelength or intensity. The low-energy shoulder, assigned to indirect gap transitions, is also virtually identical in both samples. On the high-energy side of the main peak, there is also a shoulder, similar to that observed in heavily p-type Ge and assigned to direct-gap transitions that do not conserve crystal momentum (see, Wagner and Vina, Phys. Rev. B 1984, 30, 7030-7036). An alternative explanation, in our case, would be direct-gap emission from the Ge/Si interface, where a small amount of intermixing with Si might increase the direct-gap energy. Under any of these scenarios, it is apparent that the shoulder is weaker in the Ge(Sn) sample, as might be expected for a higher-quality material.

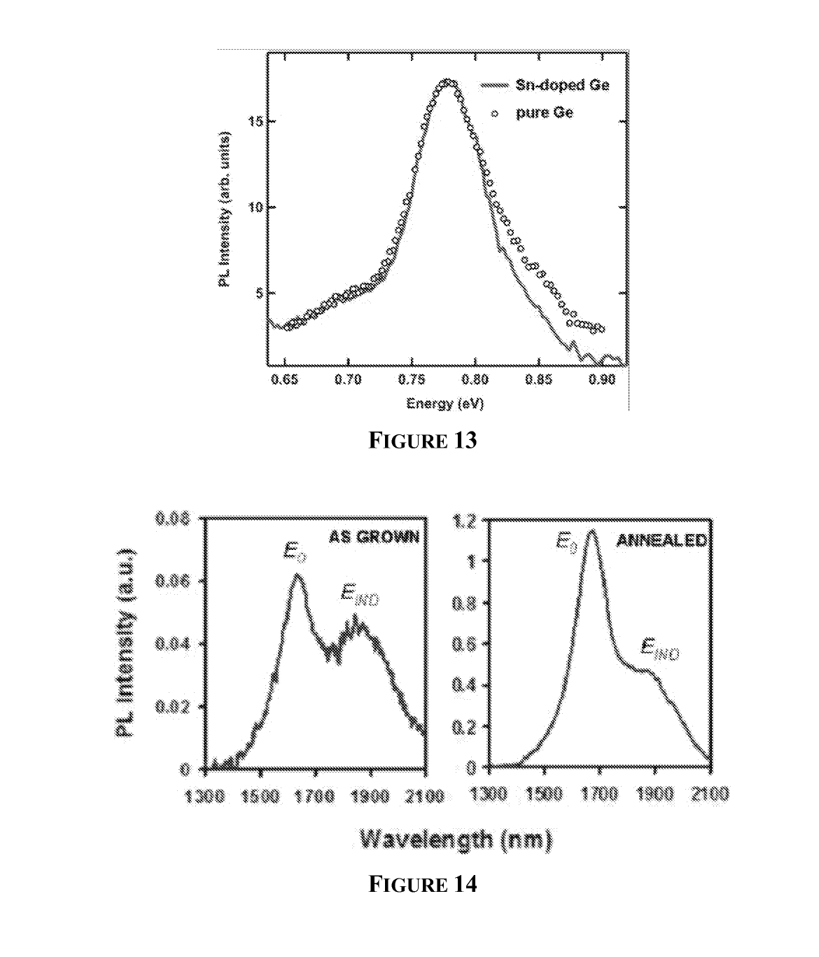

Previous work of intrinsic Ge-on-Si with similar thickness (1-1.5 μm) has demonstrated that room-temperature PL is dominated by the direct-gap emission, as shown for our intrinsic materials in FIG. 13 (see, Sun et al., J. Appl. Phys. Lett. 2009, 95, 011911; and El Kurdi et al., Appl Phys. Lett. 2009, 94, 191107). This is in contrast to the PL behavior of bulk Ge, which is characterized by a strong but broad indirect peak (E_{ind}) and a much weaker direct gap shoulder (E₀). It has also been shown that n-doping at (4-5)×10¹⁸ cm⁻³ in bulk Ge causes a measurable increase of the E₀ intensity, while the E_{ind} still remains the dominant feature. Any further increases of the direct-gap intensity in bulk Ge have thus far only been obtained by mechanically applying tensile strain in the range of 0.12%-0.37% (see Lan et al., Appl. Phys. Lett. 2011, 98, 101106).

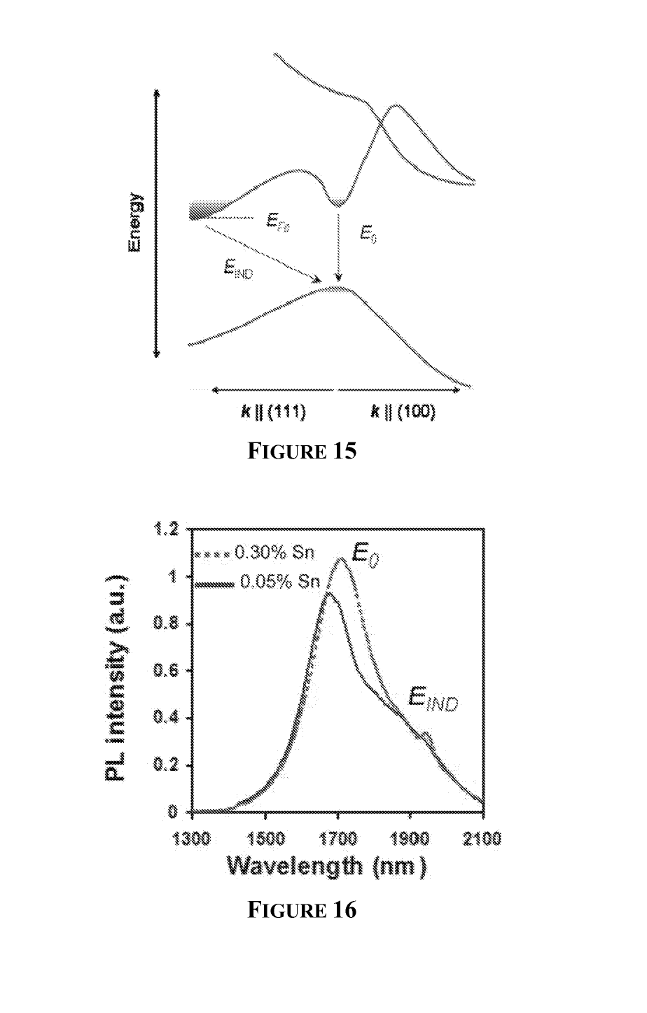

In the case of Ge-on-Si, an increase in the direct-gap PL has been observed in doped and tensile-strained samples, but most previous studies do not cover the full spectral range corresponding to indirect-gap PL. Here, we extend the emission measurements down to 2100 nm to explore the indirect-gap emission in full detail. We find that this emission is also significantly enhanced via doping. As can be seen in FIG. 14a, distinct direct and indirect peaks with comparable intensity are observed for a representative strain-free Ge(Sn) sample with a thickness of 1200 nm and a carrier density of about 2×10¹⁹ cm⁻³. To our knowledge, the PL in FIG. 14a exhibits the strongest manifestation of the indirect gap observed thus far in thin-film materials. In particular, both E₀ and E_{ind} peaks are clearly resolved at 1635 and 1865 nm, with peak intensities that differ by less than about 20%. It is important to note that the PL data shown in FIG. 13 were obtained from samples that were subjected to RTA at 725° C., while the as-grown counterparts did not show any measurable PL signal. This is in contrast to the observation of significant light emission from the n-type Ge(Sn) shown in FIG. 14a, and this is clearly a consequence of the relatively heavy doping, which introduces a sufficient carrier population at 2×10¹⁹ cm⁻³ in the conduction band, as shown by a schematic of the Ge-like electronic structure in FIG. 15.

The above observations suggest that both n-type doping and crystallinity improvement via annealing are responsible for the enhanced PL. To confirm this notion, we conducted a series of RTA experiments of the doped Ge(Sn) samples. The principal outcome is that the highest PL intensity is obtained from samples annealed at 725° C., as shown in FIG. 14b. First, we see that the overall intensity increases by more than an order of magnitude, relative to the as-grown sample, as expected for improved crystallinity. Furthermore, the direct peak position shifts from 1635 nm to about 670 nm, and the direct/indirect PL intensity ratio also increases (the direct gap PL is about 20 times more intense in the annealed sample), relative to the indirect PL (a detailed account of the shifts will be presented elsewhere). We have established via high-resolution XRD that a tensile strain of ˜0.18% is induced by the thermal treatment, while the as-grown sample is fully relaxed. This thermal strain contributes to the direct-gap emission shift as well as its relative enhancement. The tensile strain in the layers reduces the L-Γ valley separation, shifting the Γ minimum toward the Fermi level and thereby enhancing the direct transition in the material (see FIG. 15). This mechanism for light generation from Ge-like materials is reminiscent of the recently developed Ge-on-Si laser, in which the emission is achieved by optical pumping of n-type Ge structures that are both tensile strained at about 20% and doped with phosphorus at levels of about 1×10¹⁹ atoms/cm³ (see, Liu et al., Opt. Lett. 2010, 35, 679-681).

In this regard, our Ge(Sn) approach offers a low-cost, high-performance alternative to the above light source technology for applications in the 1550-nm telecom window (band) and affords a high level of control over the P and Sn contents. For example, for depositions conducted under identical conditions and with similar ratios of co-reactants, the P and Sn contents only varied by 1%-2%. Accordingly, here, we focus on independent variation of Sn content within the Ge(Sn) compositional range while maintaining a fixed dopant level of P donors. Specifically, we investigate the PL performance of our Ge(Sn) co-doped with the same P levels of 2×10¹⁹ (same as in the above samples) but with a slightly higher Sn concentration (in the vicinity of 0.3% or ˜1×10²⁰). The latter is expected to yield a meaningful energy shift, relative to the highly diluted samples, whose PL peak positions are virtually indistinguishable to those pure Ge, as shown in FIG. 13. As demonstrated above, the ˜2×10¹⁹ donor levels are not only sufficiently high to enhance light emission, but they are also thermally robust to withstand RTA processing up to 725° C. without any significant diffusion of the P atoms from lattice sites, as typically observed under these conditions for samples with higher dopant concentrations. For example, activated P densities as high as (0.7-1)×10²⁰ cm⁻³ can be achieved in as-grown samples at 350° C. using our P(GeH₃)₃ process; however, these levels are invariably reduced down to a threshold of (2-3)×10¹⁹ cm⁻³ upon annealing at 650-725° C. We note that similar levels of P concentration have been achieved by diffusion of P into Ge devices at similar temperatures (see, Posthuma et al., IEEE Trans. Electron Devices 2007, 54, 1210-1216).

Atomically flat layers with the desired 0.3% Sn content were grown by appropriately adjusting the SnD₄ amount and were subsequently annealed at 725° C. to improve the crystallinity and enhance the emission intensity. SIMS profiles indicated that the average P and Sn contents of the “as-grown” material remained unchanged in the annealed counterparts (2×10¹⁹ cm⁻³ and 0.3%, respectively). The Sn content was confirmed by RBS analysis, which showed a weak but distinctly visible Sn signal rising above the background of the measurement, indicating that the concentration is above the detection limit of ˜0.1%, as expected. XRD on- and off-axis peaks were used to determine a residual tensile strain of 0.17%-0.19% in the annealed samples. As expected, the biaxial strain reduces the energy barrier between the lower indirect-gap valley and the direct-gap counterpart (FIG. 15), resulting in a net increase of the electron population in the latter under similar external pumping conditions. FIG. 16 shows the PL spectra acquired from samples containing different concentrations of Sn (0.3% (dashed trace) and 0.05% (solid trace)) but the same amount of P (2×10¹⁹ cm⁻³). Furthermore, since they undergo similar thermal treatments, they are found to possess a common tensile strain of 0.18%, as measured by XRD. In addition, the films have comparable thicknesses, in the range of 880-900 nm; therefore their PL intensities can be compared on equal footing. We notice that the main, direct-gap peak in the spectrum of the 0.30% Sn material is red-shifted and its intensity is slightly higher, relative to the 0.05% Sn counterpart. Both effects can be explained by the increase in Sn incorporation, which lowers the direct-gap energy and reduces its separation from the indirect gap, which leads to a larger electron population in the Γ valley (see FIG. 15). This causes a stronger direct-gap emission. The reduction in the Γ-L separation is apparent in FIG. 16, where the peak maximum for the indirect gap emission (broad shoulder-like features) is similar in both materials, whereas a clear energy downshift is observed for the direct emission.

For another of the quality of the Ge(Sn) materials, we fabricated n-i-p diodes, incorporating layers containing 0.05% Sn and grown on highly n-doped 4-in. Si(100) wafers (F=0.003 Ωcm). The diode typically consists of an about 850-nm-thick intrinsic film, followed by a 150-nm p-type capping overlayer. The latter was produced by adding appropriate amounts of diborane into the reaction mixture. After growth, the structures were subjected to three RTA cycles at 680° C., for 10 s each.

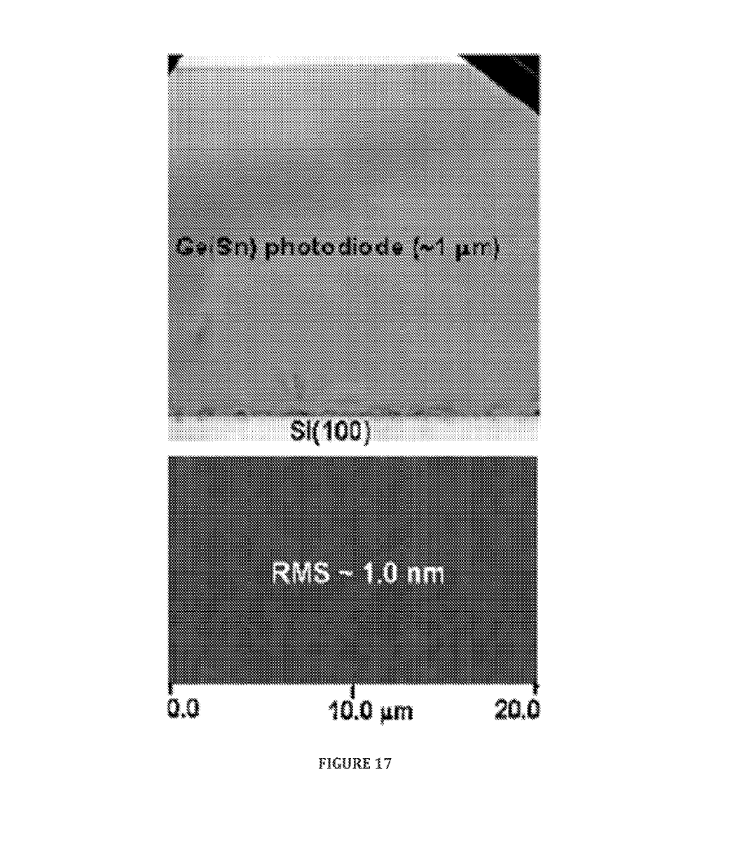

Samples were processed using protocols similar to those used to fabricate Ge_{0.98}Sn_{0.02} alloy photodiodes, described above. In this case, circular mesas with diameters ranging from 50 μm to 3000 μm were defined by photolithography and etched using reactive ion plasmas generated by BCl₃. The mesas were passivated by a 270-nm-thick SiO₂ layer, which also serves as antireflection coating. The Cr/Au metal contacts were deposited by e-beam and defined by lithography. Post processing XTEM investigations of the p-i-n devices reveal a near-perfect microstructure, suggesting that the relatively harsh fabrication steps do not cause any damage in the form of cracks, surface roughness, interface dislocations, and threading defects (see FIG. 17). Atomic force microscopy (AFM) images of the same material indicated an rms roughness of about 1 nm, indicating a flat surface morphology, which is consistent with the minimal level of defects detected by XTEM. These are highly encouraging results from the point of view of the reliability of our Ge(Sn)-on-Si diode technology.

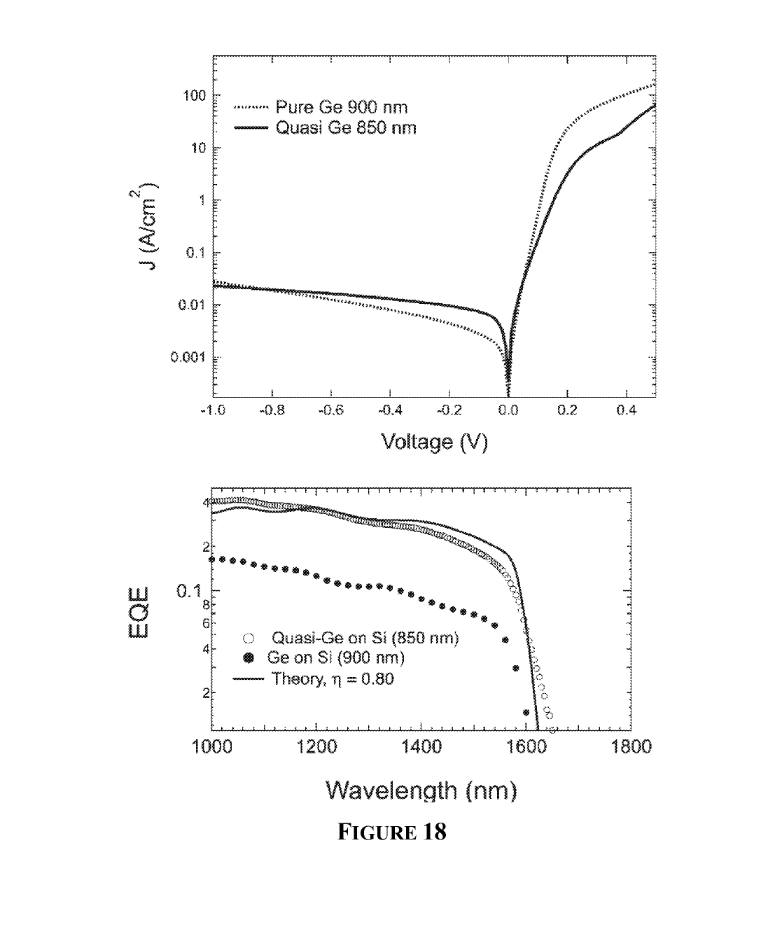

Current density versus voltage (I-V) measurements of the fabricated devices were conducted, and a representative curve for a typical 100-μm device is shown in FIG. 18, where it is compared with the data measured from a Ge (900 nm) reference sample produced using our specialty low-pressure CVD (˜10⁻⁴ Torr) approach (see Wistey et al., AppL Phys. Lett. 2007, 90, 082108). Both curves exhibit a similar functional form, indicating clear rectifying behavior. Typical dark current density for the Sn-doped Ge device at −1V bias is ˜0.02 A/cm², which is comparable to the 0.027 A/cm² value found in corresponding pure Ge devices grown on Si. These current density levels are consistent with high-quality material possessing threading defect densities of <10⁵/cm². The low dark currents observed here are also consistent with a negligible degree of alloy scattering in these highly dilute alloys.

The spectral responsivity of the photodiodes, measured at zero bias, is plotted in FIG. 18 and compared with corresponding data for a pure Ge reference device in p-i-n geometry. Both curves show a sharp decrease in the vicinity of about 1600 and 1640 nm, respectively, corresponding to the direct-gap absorption edge. Both samples exhibit similarly high degrees of crystallinity, as evidenced by the fwhm of their 004 and 224 reflections in the XRD spectra. The Sn-doped material has a residual strain of 0.18%, compared to 0.1% in Ge. This strain accounts for the optical shift of about 30 nm between the two devices. A theoretical calculation of the EQE using the model of Roucka et al. (IEEE J. Quant. Electron. 47 (2), 213 (2011)) reveals that the collection efficiency at zero bias is η≈80% in the Ge(Sn) diode, whereas the pure Ge diode had a collection efficiency of η=34%. The superior collection efficiency of the Ge(Sn) diode probably indicates a lower level of residual doping in the nominally intrinsic layer.

Incorporation of dopant levels of Sn into Geon-Si films at nominal levels of 0.05-0.15 is sufficient to completely suppress the traditional island-like growth mode (Stranski-Krastanov) and produce high-quality layers with flat surfaces and fully relaxed microstructures. Films with thicknesses up to 5 μm are commonly produced at high growth rates (up to 30 nm/min), suggesting that this batch wafer process may represent a scalable, high-volume, and high-throughput CVD method for producing Ge-based materials for applications in photonics, including photovoltaics. These films can be systematically co-doped with P atoms at controlled levels of up to 2×10¹⁹ cm³, and this allows tuning of the photoluminenscence (PL) profile, with respect to direct and indirect transitions, for the first time. Optimizations of the film quality using a single rapid thermal annealing (RTA) step and the precise control of doping levels and Sn content have produced unprecedented PL intensities for this class of thin-film materials, suggesting that applications in emitters akin to the reported Ge-on-Si laser are within reach. Furthermore, the fabrication of high-performance photodiode prototypes opens the door to applications in infrared (IR) telecom detectors. In this regard, our approach offers a low-cost, high-performance alternative or complement to the above light source technologies for applications in the 1550-nm telecom window.

### Example 10

Photoluminescence (PL) studies of n-type Ge_{1-y}Sn_{y} alloys were conducted on samples with 0<y<0.036 and thicknesses between 400 nm and 900 nm. They were grown at 320-385° C. directly on high resistivity Si(100) using low pressure CVD reactions of SnD₄ and Ge₂H₆. All materials were doped in situ using the single-source precursor P(GeH₃)₃. The donor carrier concentrations were found to be in the 2-6×10¹⁹ cm⁻³ range from Hall effect and infrared ellipsometry measurements. Secondary ion mass spectrometry (SIMS) depth profiles revealed an uniform distribution of the P atoms throughout the layer. The P content was quantified using an implanted Ge standard, and the results indicate that, within error, all P donors are activated before any post-growth thermal treatment. The Sn content and thickness of all films were measured by Rutherford backscattering (RBS), which was also employed to investigate the degree of crystallinity and epitaxial registry of the layer using block ion channeling experiments. The ratio of the aligned and random peak heights was found to be identical in both the Sn and Ge signals of the spectrum, indicating full substitution of the constituent atoms in the lattice. High-resolution x-ray diffraction (HRXRD) reciprocal space maps of the as-grown materials revealed a residual compressive strain in the about 0.20% range. The full width at half maximum (FWHM) of the 004 rocking curve was relatively broad at 0.7°, indicating a non-negligible mosaic spread. The crystallinity is dramatically improved by a post-growth rapid thermal annealing (RTA) treatment described below. The relaxed lattice parameter is obtained from the HRXRD data and compared with the measured compositional dependence in Beeler et al. (Phys. Rev. B 84(3), 035204 (2011)). Very good agreement is found between the compositions determined from RBS and HRXRD.

The PL measurements were conducted at room temperature using a 980 nm laser focused to an about 100 μm spot. The power incident on the samples was set to 400 mW. The emitted light was focused onto the entrance slit of an ƒ=320 mm spectrometer that was equipped with a diffraction grating blazed at 2000 nm. The diffracted light was collected by a liquid-nitrogen cooled extended InGaAs detector. The PL signal contained a narrow contribution at 1950 nm corresponding to the laser line observed in second-order. This peak was fitted with a Gaussian profile and subtracted from the spectra for clarity of the presentation.

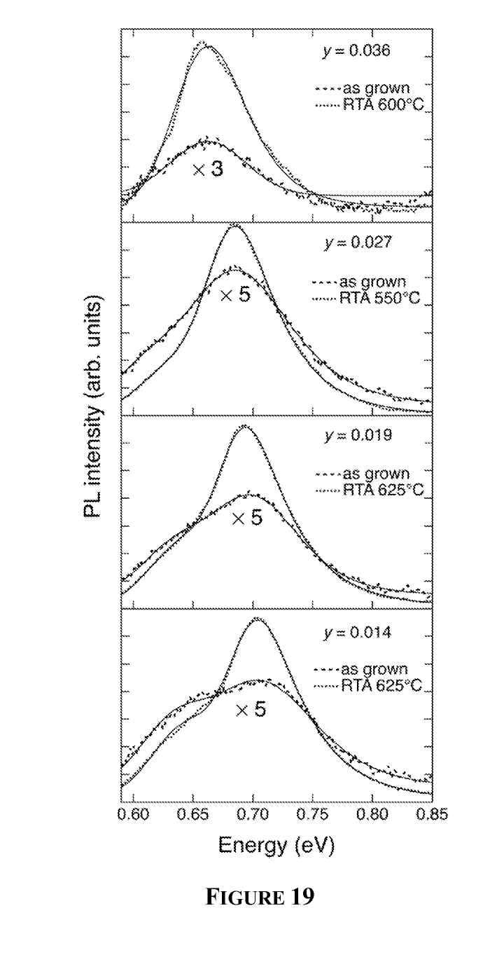

PL spectra for representative samples are shown in FIG. 19. All spectra display a dominant high-energy peak and a lower-energy shoulder. They are assigned to emission from the direct and indirect gap, respectively. The solid lines show fits in which the indirect emission is modeled as a Gaussian peak with a fixed FWHM of 67 meV, the value we obtain from fitting the bulk Ge data from Haynes, Phys. Rev. 98(6), 1866 (1955). The direct emission is modeled as an exponentially modified Gaussian curve (EMG) to account for the temperature-dependent high-energy tail. The EMG component is then fit with a theoretical expression for direct gap emission, based on a generalized Van Roosbroeck-Shockley expression that uses a realistic model for the direct gap absorption, including strain and excitonic effects. The model computes the direct gap emission only, but the L valleys associated with indirect emission are fully taken into account for the calculation of quasi-Fermi levels. Thus, changes in the relative intensity of direct and indirect emission (proportional to the ratio nC/nL between the electron concentrations at the Γ and L valleys) can also be predicted.

It is apparent from a simple inspection of FIG. 19 that there is a progressive red shift of the PL as the Sn concentration is increased. The observation of PL in as-grown materials is remarkable, since intrinsic Ge_{1-y}Sn_{y}/Si(100) layers only yield measurable emission signals after annealing (see, Mathews et al., Appl. Phys. Lett. 97(22), 221912 (2010)). In fact, the PL intensity from our as-grown doped films is of the same order of magnitude as the PL intensity from annealed undoped films. Samples with similar Sn concentrations and layer thickness typically exhibit a significant increase in emission intensity as a function of doping levels from 1-2×10¹⁹ cm⁻³ to 6×10¹⁹ cm⁻³.

An enhancement of the PL intensity has been reported for doped pure Ge (see, El Kurdi et al., Appl. Phys. Lett. 94(19), 191107 (2009); and Sun et al., Appl. Phys. Lett. 95(1), 011911 (2009)). To further investigate this phenomenon in our Ge_{1-y}Sn_{y} alloys, we performed annealing studies. All samples underwent RTA cycles (typically 3-10 s) at temperatures between 625° C. and 700° C., with lower temperatures being used on higher Sn-concentration samples. The thermal treatment resulted in a significant improvement of the crystallinity, as evidenced by the narrowing of the 004 rocking curve down to a FWHM of 0.15°. The RTA treatment also induces a change in the nature of the residual strain, from compressive to tensile (about 0.1%), and a decrease in the carrier concentrations by a factor of approximately 2. PL results from RTA-treated samples are shown in FIG. 19. We observe in all cases intensity enhancements (integrated areas) by factors between 6 and 10. We have computed the changes in direct emission intensity and direct/indirect intensity ratios caused by the changes in strain and carrier concentration, and we find that these contributions tend to cancel each other, since the tensile strain increases the relative population of the Γ-valley, whereas a decrease in carrier concentration produces the opposite effect. Thus, the observed increases in PL intensity upon annealing must be due to a reduction in non-radiative recombination rates as a result of the improved crystallinity of the annealed samples. This is strongly supported by the sharper PL line-shapes: for the as-grown samples, the Gaussian broadening of the EMG has a FWHM of about 80 meV, which is reduced to about 50 meV upon annealing.

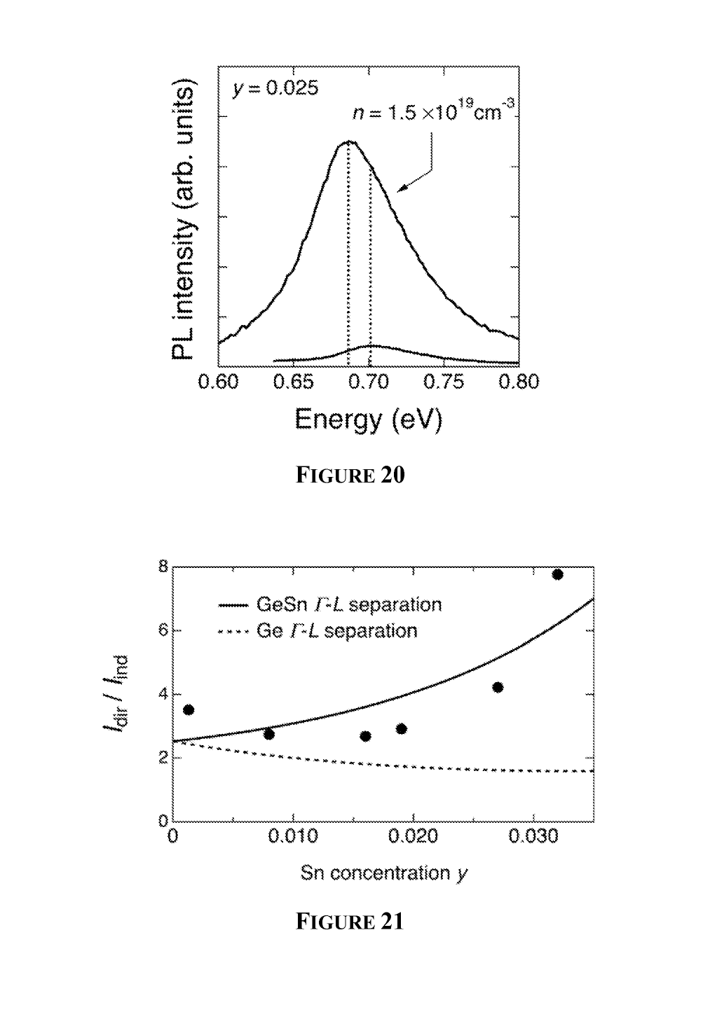

The PL intensity from doped, annealed samples can now be directly compared with their undoped counterparts. FIG. 20 shows results from similar samples with a Sn concentration y=0.025. The doped sample was annealed at 625° C., whereas the undoped material was annealed at 680° C. The PL intensity from the doped sample is about 10 times stronger. From fits of the undoped sample PL with our theoretical expressions, we conclude that the steady-state photoexcited hole concentration cannot be higher than 10¹⁸ cm⁻³. Using this value, we predict that the doped sample intensity should be 15 times stronger, in reasonable agreement with the observed value. These results thus confirm that n-type doping at the 10¹⁹ cm⁻³ level and RTA at temperatures near 600° C. have a comparable effect in terms of PL intensity enhancement, quantitatively confirming that the observation of PL in as-grown doped samples is directly related to their doping levels.

Annealing the Sn-rich samples at T>650° C. results in a dramatic quenching of the emission intensity and a concomitant shift of the corresponding direct gap to higher energy, suggesting that a significant fraction of the Sn atoms has shifted off their tetrahedral sites. This was confirmed using RBS, which showed that the profile of the aligned signal intensity has uniformly increased to a significant level halfway between that of the as-grown sample and the fully random counterpart. However, the random Sn trace remained constant throughout the layer, indicating no Sn segregation towards the film surface. The chemical environment of the Sn atoms in these “partially decomposed” samples is not fully understood and warrants further investigation. However, preliminary XRD measurement indicates a systematic reduction in the molar volume of the system, which can be explained by an offset of the atoms from the ideal diamond lattice positions.

An interesting byproduct of our study of doped samples is the observation that their emission is systematically redshifted relative to undoped films with the same Sn concentration, as seen in FIG. 20. Theoretical fits of the two samples in this figure give a direct band gap of E₀=0.707 eV for the undoped sample and E₀=0.684 eV in the doped one. The relative shifts are comparable to those observed in absorption measurements from doped Ge, where they are attributed to band gap renormalization (see, Haas, Phys. Rev. 125(6), 1965 (1962)).

FIG. 21 shows the observed intensity ratios I_{dir}/I_{ind} between direct and indirect emission for our annealed doped samples. The lines are proportional to the calculated n_{Γ}/n_{L} population ratio. Since the RTA temperature is systematically lowered as a function of y, the residual tensile strain is a smoothly decreasing function of y, and this is incorporated into the n_{Γ}/n_{L} calculation. The dotted line is computed assuming no compositional dependence of the Γ-L separation, and predicts a decreasing I_{dir}/I_{ind} as a function of y due to the reduced tensile strain for higher y. The solid line incorporates the decrease in the Γ-L separation as a function of y and gives better agreement with experiment, confirming that Sn-alloying can be used as an alternative to tensile strain to enhance the direct gap emission in Ge.

In summary, we have measured strong room temperature photoluminescence in n-type GeSn alloys. These films are found to be much better light emitters than intrinsic analogs with similar Sn contents. This behavior is explained by the increase in the electron population delivered through doping with P donors. Studies of intensity ratios between direct and indirect emission confirm that allciying with Sn is a viable alternative to tensile strain as a tool to enhance direct gap emission in Ge-like materials.

The above-described invention possesses numerous advantages as described herein and in the referenced appendices. The invention in its broader aspects is not limited to the specific details, representative devices, and illustrative examples shown and described. Accordingly, departures may be made from such details without departing from the spirit or scope of the general inventive concept.

We claim:

1. An alloy of the formula Ge₁₋ₓSnₓ, wherein x is greater than 0 and less than or equal to about 0.003, wherein the alloy is optionally n-doped and/or p-doped.

2.-9. (canceled)

10. An assembly comprising
(a) a substrate comprising Si; and
(b) a Ge(Sn) alloy layer consisting essentially of the Ge₁₋ₓSnₓ alloy of claim 1 formed over the substrate.

11. (canceled)

12. The assembly of claim 10, wherein the substrate comprises n-doped Si or p-doped Si.

13. The assembly of claim 10, wherein the substrate comprises Si(100).

14. The assembly of claim 10, wherein the substrate comprises miscut Si (100).

15. The assembly of claim 10, wherein the substrate comprises silicon on insulator.

16. The assembly of claim 10, wherein the Ge(Sn) alloy layer is atomically smooth.

17. The assembly of claim 10, wherein the Ge(Sn) alloy layer is essentially unstrained.

18. A method for forming an assembly comprising contacting a surface layer of a substrate with a vapor comprising Ge₂H₆ and SnD₄ under conditions suitable for forming a Ge(Sn) alloy of the formula Ge₁₋ₓSnₓ, layer over the surface layer, wherein x is greater than 0 and less than or equal to about 0.003, and wherein the surface layer comprises Si.

19. The method of claim 18, wherein the contacting occurs at a temperature between about 360° C. and 420° C.

20. The method of claim, wherein the Ge(Sn) alloy layer is formed directly on the substrate.

21. The method of claim 18, wherein the Ge(Sn) alloy layer is formed at a rate between about 1 nm/min and 30 nm/min.

22. The method of claim 18, further comprising annealing the Ge(Sn) alloy layer.

23. (canceled)

24. The method of claim 18, further comprising forming a doped Ge(Sn) alloy layer over the Ge(Sn) alloy layer.

25. A photodiode comprising, a doped substrate having a surface layer; an intrinsic Ge(Sn) alloy layer formed directly over the Si surface layer; and a second Ge(Sn) alloy layer directly over the intrinsic Ge(Sn) alloy layer, wherein one of the substrate surface layer and the second Ge(Sn) alloy layer is p-doped and the other is n-doped.

26. The photodiode of claim 25, wherein the second doped Ge(Sn) alloy layer has an x value less than the intrinsic Ge(Sn) alloy layer.

27. (canceled)

28. An avalanche photodetector comprising a photodiode according to claim 25.

29. A photonic circuit element comprising a photodiode of claim 25, and a waveguiding structure in optical communication with the photodiode.

30. The photonic circuit element of claim 29, further comprising a light emitting diode in optical communication with the waveguiding structure.

31. An array comprising a plurality of photodiodes according to claim 25, arranged in a predetermined arrangement.

32.-33. (canceled)
